(19) United States
(12) Patent Application Publication
(10) Pub. No.: US 2024/0383931 A1
(43) Pub. Date: Nov. 21, 2024

(54) PHOSPHORUS-CONTAINING COMPOUND, MANUFACTURING METHOD THEREOF, RESIN COMPOSITION, AND ARTICLE MADE THEREFROM

(71) Applicant: ELITE ELECTRONIC MATERIAL (KUNSHAN) CO., LTD., Kunshan City (CN)

(72) Inventors: Yan ZHANG, Kunshan City (CN); Jun DU, Kunshan City (CN); Diya LIU, Kunshan City (CN)

(73) Assignee: ELITE ELECTRONIC MATERIAL (KUNSHAN) CO., LTD., Kunshan City (CN)

(21) Appl. No.: 18/220,671

(22) Filed: Jul. 11, 2023

(30) Foreign Application Priority Data
May 19, 2023 (CN) 202310572481.2

(51) Int. Cl. C07F 9/53; C07F 9/32; C07F 9/40; C07F 9/50; C08F 261/06

(52) U.S. Cl. CPC C07F 9/5325; C07F 9/3241; C07F 9/4056; C07F 9/5072; C08F 261/06; C08K 2201/002

(57) ABSTRACT

The present disclosure provides a phosphorus-containing compound represented by Formula (1), a resin composition comprising the phosphorus-containing compound, and an article made from the resin composition. The phosphorus-containing compound can achieve halogen-free flame retardancy while satisfying the requirements of excellent dielectricity, high copper foil peeling strength, high glass transition temperature, low percent thermal expansion and excellent heat resistance after moisture absorption. The resin composition comprises the following components or a prepolymer thereof: (A) 100 parts by weight of an unsaturated C═C double bond-containing polyphenylene ether resin; and (B) 15 parts by weight to 90 parts by weight of the phosphorus-containing compound represented by Formula (1); wherein the prepolymer is obtained from a mixture through prepolymerization, and the mixture comprises at least the component (A) and the component (B).

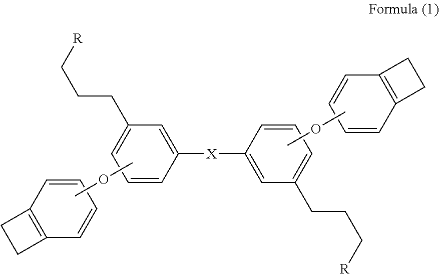

### CROSS-REFERENCE TO RELATED APPLICATIONS

This non-provisional application claims priority under 35 U.S.C. § 119 (a) on patent application No. 202310572481.2 filed in China on May 19, 2023, the entire contents of which are hereby incorporated by reference.

### BACKGROUND

### 1. Technical Field

This disclosure relates to a phosphorus-containing compound, a manufacturing method thereof, a resin composition, and an article made therefrom, particularly to a phosphorus-containing compound which can be applied to a prepreg, a resin film, a laminate and a printed circuit board, and a resin composition thereof.

### 2. Related Art

Recently, with the rapid development of 5G electronic information technology, the signal processing speed and transmission frequency of various electronic equipments applied in the communication field have increased significantly, the powers of electronic devices have increased continuously, and the operating temperatures thereof have also raised continuously. In order to keep electronic components working properly, the circuit laminate needs not only excellent dielectricity but also high reliability in flame retardancy, high glass transition temperature, low percent thermal expansion and excellent heat resistance after moisture absorption.

Traditional circuit laminates have flame retardancy mainly through adding a bromine-containing flame retardant to the main resin or modifying the main resin by bromination, but these electronic products containing halogen such as bromine may generate great amounts of toxic and harmful substances such as dioxin and hydrogen halide during their waste combustion process. With the increasing public awareness of environmental protection, these halogen-containing circuit laminates are gradually obsolete, and halogen-free materials of circuit laminates become a studying hotspot in the industry. Currently, people achieve the purpose of halogen-free flame retardancy mainly by adding phosphorus-containing compounds into a resin composition. However, in the prior art, there is no phosphorus-containing compound that can realize halogen-free flame retardancy while satisfying the requirements of excellent dielectricity, high copper foil peeling strength, high glass transition temperature, low percent thermal expansion and excellent heat resistance after moisture absorption. Therefore, under the dual requirements of high environmental protection and high performance, a new type of halogen-free flame retardant materials with good comprehensive performance has become a goal people in the industry heading for.

### SUMMARY

The present disclosure provides a phosphorus-containing compound, a manufacturing method thereof, a resin composition containing the phosphorus-containing compound, and an article made from the resin composition, such as a prepreg, a resin film, a laminate and a printed circuit board, which is able to solve the problems described above.

The phosphorus-containing compound of the present disclosure is represented by Formula (1):

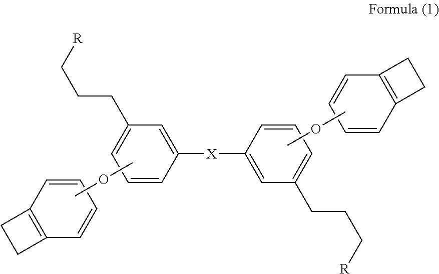

wherein in Formula (1), X is a covalent bond or a C1-C3 alkyl group,
each of R is independently a group represented by Formula (2), Formula (3) or Formula (4),

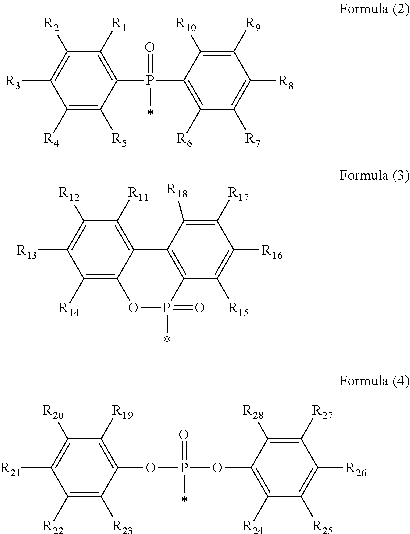

wherein each of R₁ to R₂₈ is independently a hydrogen atom or a C1-C3 alkyl group.

Preferably, the phosphorus-containing compound is any one of phosphorus-containing compounds represented by Formula (5) to Formula (9).

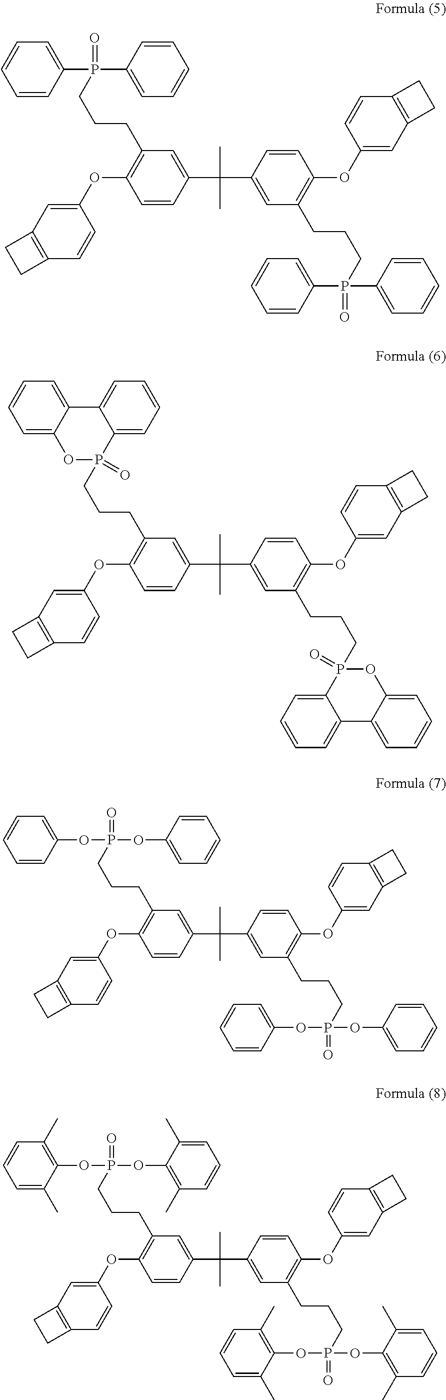 [SMILES: CC(C)(c1ccc(Oc2ccc3c(c2)CC3)c(CCCP(=O)(c2ccccc2)c2ccccc2)c1)c1ccc(Oc2ccc3c(c2)CC3)c(CCCP(=O)(c2ccccc2)c2ccccc2)c1 ; CC(C)(c1ccc(Oc2ccc3c(c2)CC3)c(CCCP2(=O)Oc3ccccc3-c3ccccc32)c1)c1ccc(Oc2ccc3c(c2)CC3)c(CCCP2(=O)Oc3ccccc3-c3ccccc32)c1 ; CC(C)(c1ccc(Oc2ccc3c(c2)CC3)c(CCCP(=O)(Oc2ccccc2)Oc2ccccc2)c1)c1ccc(Oc2ccc3c(c2)CC3)c(CCCP(=O)(Oc2ccccc2)Oc2ccccc2)c1 ; Cc1cccc(C)c1OP(=O)(CCCc1cc(C(C)(C)c2ccc(Oc3ccc4c(c3)CC4)c(CCCP(=O)(Oc3c(C)cccc3C)Oc3c(C)cccc3C)c2)ccc1Oc1ccc2c(c1)CC2)Oc1c(C)cccc1C]

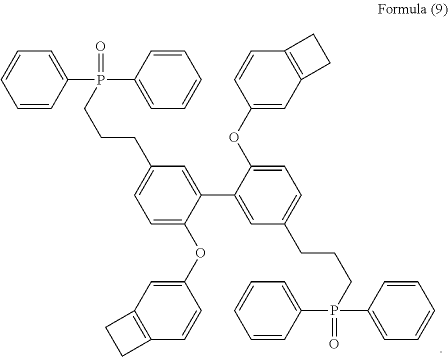 [SMILES: O=P(CCCc1ccc(Oc2ccc3c(c2)CC3)c(-c2cc(CCCP(=O)(c3ccccc3)c3ccccc3)ccc2Oc2ccc3c(c2)CC3)c1)(c1ccccc1)c1ccccc1]

The manufacturing method of the phosphorus-containing compound comprises the following steps:
step (1): preparing a Grignard reagent of halobenzocyclobutene in a reaction vessel;
step (2): reacting diallylbisphenol with one or more of compound R—H in another reaction vessel to obtain an intermediate compound 1, wherein in the compound R—H, H represents a hydrogen atom, and R is a group represented by Formula (2), Formula (3) or Formula (4),

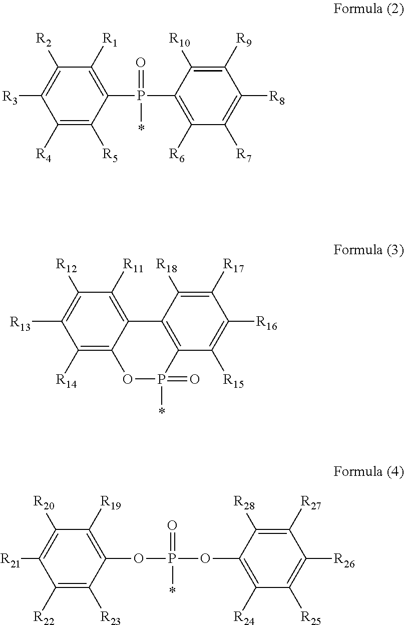

wherein each of R₁ to R₂₈ is independently a hydrogen atom or a C1-C3 alkyl group; and
step (3): reacting the Grignard reagent of halobenzocyclobutene prepared from the step (1) with the intermediate compound 1 to obtain the phosphorus-containing compound represented by Formula (1).

In the manufacturing method of the phosphorus-containing compound, the reaction temperature for the step (1) is 0° C. to 100° C., and the reaction time for the step (1) is 1 to 10 hours, in the step (2), the compound R—H is diphenylphosphine oxide, 9,10-dihydro-9-oxa-10-phosphaphenanthrene-10-oxide, diphenyl phosphate or bis(2,6-dimethylphenyl)phosphate, and the molar ratio of the compound R—H to the diallylbisphenol is 2:1 to 3:1,
the reaction temperature for the step (2) is 80° C. to 160° C., and the reaction time for the step (2) is 1 to 6 hours, and
the reaction temperature for the step (3) is −20° C. to 120° C., and the reaction time for the step (3) is 3 to 30 hours.

The present disclosure also provides a resin composition, comprising the following components or a prepolymer thereof:
component (A): 100 parts by weight of an unsaturated C═C double bond-containing polyphenylene ether resin; and
component (B): 15 parts by weight to 90 parts by weight of the phosphorus-containing compound described above;
wherein the prepolymer is obtained from a mixture through prepolymerization, and the mixture comprises at least the component (A) and the component (B).

Preferably, the component (A) comprises any one of a (meth)acryloyl-containing polyphenylene ether resin, a vinylbenzyl-containing polyphenylene ether resin, and a vinyl-containing polyphenylene ether resin, or a combination thereof.

Preferably, the phosphorus-containing compound comprises any one of phosphorus-containing compounds represented by Formula (5) to Formula (9), or a combination thereof,

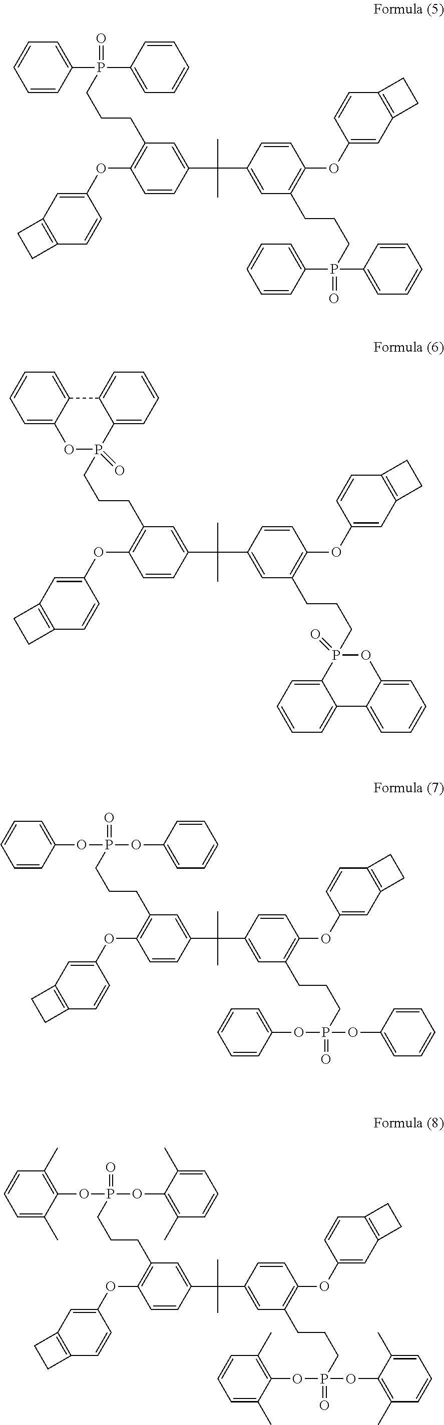

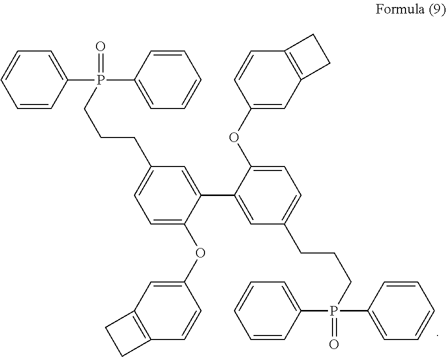 [SMILES: O=P(CCCc1ccc(Oc2ccc3c(c2)CC3)c(-c2cc(CCCP(=O)(c3ccccc3)c3ccccc3)ccc2Oc2ccc3c(c2)CC3)c1)(c1ccccc1)c1ccccc1]

Preferably, the prepolymer is formed from the component (A) and the component (B) through prepolymerization, and the conversion rate of the prepolymerization is 10% to 99%.

The resin composition may further comprise any one of an unsaturated C═C double bond-containing crosslinking agent, an organic silicone resin, a benzoxazine resin, an epoxy resin, a polyester resin, a phenol resin, an amine curing agent, a polyamide, a polyimide, a styrene maleic anhydride, a maleimide resin, a cyanate ester resin, and a maleimide triazine resin, or a combination thereof.

The resin composition may further comprise any one of a curing accelerator, a polymerization inhibitor, an inorganic filler, a surfactant, a coloring agent, and a solvent, or a combination thereof.

The present disclosure provides an article made from the resin composition described above, the article comprises a prepreg, a resin film, a laminate or a printed circuit board.

The article has at least one of the following properties:
a glass transition temperature as measured by reference to IPC-TM-650 2.4.24.4 of greater than or equal to 240° C.;
a dielectric constant at 10 GHz as measured by reference to JISC2565 of less than or equal to 3.20;
a dissipation factor at 10 GHz as measured by reference to JISC2565 of less than or equal to 0.0020;
a flame retardancy as measured by reference to UL94 rating of V0;
a percent thermal expansion at Z-axis as measured by reference to IPC-TM-650 2.4.24.5 of less than or equal to 1.5%;
no delamination occurs after subjecting the article to a heat resistance after moisture absorption test by reference to IPC-TM-650 2.6.16.1 and IPC-TM-650 2.4.23;
a copper foil peeling strength as measured by reference to IPC-TM-650 2.4.8 of greater than or equal to 3.2 lb/in.

### BRIEF DESCRIPTION OF THE DRAWINGS

The present disclosure will become more fully understood from the detailed description given hereinbelow and the accompanying drawings which are given by way of illustration only and thus are not intended to limit of the present disclosure and wherein:

FIG. 1 illustrates an FTIR spectrum of P1 as an example of the phosphorus-containing compound in one embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

In order to enable those skilled in the art to understand the features and effects of the present disclosure, the following mentioned terms and words in the specification and claims will generally be illustrated and defined. Unless otherwise specified, all technical and scientific words used herein have the common meaning as understood by those skilled in the art in regard to the present disclosure. It should be based on the definition in the specification when there is a conflict.

Whether the disclosed theories or mechanisms as described herein are right or wrong, it should not limit the scope of the present disclosure by any means, i.e, the content in the present disclosure may be implemented without limited by any specific theories or mechanisms.

As used herein, “a,” “an,” or any similar expression is used to describe components and features of the present disclosure. This is done only for convenience and to give a general sense of the scope of the present disclosure. Therefore, it should be understood that this description includes one or at least one and the singular also includes the plural unless it is obvious to mean otherwise.

As used herein, the term “comprise,” “include,” “have,” “contain,” or the like belongs to open-ended transitional phrase, intended to cover a non-exclusive inclusion. For example, a composition or article made therefrom including a plurality of factors covering any one of the listed factors, which is not limited to the factors listed herein but may include other factors not clearly listed or usually inherent to such composition or article made therefrom. Besides, unless a contrary illustration presents clearly, the term “or” refers to an inclusive “or” not to an exclusive “or”. For example, any one of the following conditions satisfies the conditions “A or B”: A is true (or present) and B is false (or not present); A is false (or not present) and B is true (or present); and A and B are true (or present). Besides, the term “comprise,” “include.” “have.” “contain,” herein should be understood that close-ended transitional phrases such as “consisting of,” “composed by,” “remainder being.” and partially open-ended transitional phrases such as “consisting essentially.” “primarily consisting of,” “composed primarily by,” “basically contain,” “consisting basically of,” “composed basically by,” “essentially contain,” are also disclosed and included.

As used herein, “or a combination thereof” means “or any combination thereof”, which covers any combination of two or more of the listed factors. The term “any” means “any one.” For example, “a composition or article made therefrom including A, B, C or a combination thereof” is interpreted as covering the following conditions: A is true (or present) and B and C are false (or not present); B is true (or present) and A and C are false (or not present); C is true (or present) and B and A are false (or not present); A and B are true (or present) and C is false (or not present); A and C are true (or present) and B is false (or not present); B and C are true (or present) and A is false (or not present); and A, B and C are true (or present), and other factors not clearly listed or usually inherent to such composition or article made therefrom.

As used herein, features and conditions such as values, numbers, contents, amounts or concentrations are presented as a numerical range or a percentage range merely for convenience and brevity. Therefore, a numerical range or a percentage range should be interpreted as encompassing and specifically disclosing all possible subranges and individual numerals or values therein, including integers and fractions, particularly all integers therein.

For example, a range of “1.0 to 8.0” or “between 1.0 and 8.0” should be understood as explicitly disclosing all subranges such as 1.0 to 8.0, 1.0 to 7.0, 2.0 to 8.0, 2.0 to 6.0, 3.0 to 6.0, 4.0 to 8.0, 3.0 to 8.0 and so on and encompassing the endpoint values, particularly subranges defined by integers, as well as disclosing all individual values in the range such as 1.0, 2.0, 3.0, 4.0, 5.0, 6.0, 7.0 and 8.0. Unless otherwise defined, the interpretation rule should be applied throughout the present disclosure regardless of broadness of the scope.

Whenever amount, concentration or other numeral or parameter is expressed as a range, a preferred range or a series of upper and lower limits, it is understood that all ranges defined by any pair of the upper limit or preferred value and the lower limit or preferred value are specifically disclosed, regardless whether these ranges are explicitly described or not. In addition, unless otherwise defined, whenever a range is mentioned, the range should be interpreted as inclusive of the endpoints and every integers and fractions in the range.

Given the intended purposes and advantages of this disclosure are achieved, numerals or figures have the precision of their significant digits. For example, 40.0 should be understood as covering a range of 39.50 to 40.49.

As used herein, a Markush group or a list of items is used to describe examples or embodiments of the present disclosure. A skilled artisan will appreciate that all subgroups of members or items and individual members or items of the Markush group or list can also be used to describe the present disclosure. For example, when X is described as being “selected from a group consisting of X1, X2 and X3”, it is intended to disclose the situations of X is X1 and X is X1 and/or X2 and/or X3. In addition, when a Markush group or a list of items is used to describe examples or embodiments of the present disclosure, a skilled artisan will understand that any subgroup or any combination of the members or items in the Markush group or list may also be used to describe the present disclosure. Therefore, for example, when X is described as being “selected from a group consisting of X1, X2 and X3” and Y is described as being “selected from a group consisting of Y1, Y2 and Y3,” the disclosure encompasses any situations of X is X1 and/or X2 and/or X3 and Y is Y1 and/or Y2 and/or Y3.

If not specified, in the present disclosure, a compound refers to a chemical substance formed by two or more elements bonded with chemical bonds and may comprise a small molecule compound and a polymer compound, but not limited thereto. Any compound disclosed herein is interpreted to not only include a single chemical substance but also include a class of chemical substances having the same kind of components or having the same property.

If not specified, in the present disclosure, a polymer refers to the product formed by monomer(s) via polymerization and usually comprises multiple aggregates of polymers respectively formed by multiple repeated simple structure units by covalent bonds; the monomer refers to the compound forming the polymer. A polymer may comprise a homopolymer, a copolymer, a prepolymer, etc., but not limited thereto. A homopolymer refers to the polymer formed by the polymerization of one monomer. Copolymers comprise: random copolymers, such as a structure of -AABABBBAAABBA-; alternating copolymers, such as a structure of -ABABABAB-; graft copolymers, such as a structure of -AA(A-BBBB)AA(A-BBBB)AAA-; and block copolymers, such as a structure of -AAAAA-BBBBBB-AAAAA-. For example, a styrene-butadiene copolymer disclosed herein is interpreted as comprising a styrene-butadiene random copolymer, a styrene-butadiene alternating copolymer, a styrene-butadiene graft copolymer, a styrene-butadiene block copolymer or a combination thereof. A prepolymer refers to a polymer having a lower molecular weight between the molecular weight of monomer and the molecular weight of final polymer, and a prepolymer contains a reactive functional group capable of participating further polymerization to obtain the final polymer product which has been fully crosslinked or cured. The term “polymer” includes but is not limited to an oligomer. An oligomer, also known as low polymer, refers to a polymer with 2 to 20, typically 2 to 5, repeating units.

If not specified, “resin” as used herein is a common name of a synthetic polymer, and is interpreted as including monomer and its combination, polymer and its combination or a combination of monomer and its polymer, and not limited thereto.

If not specified, in the present disclosure, a modification includes a product derived from a resin with its reactive functional group modified, a product derived from a prepolymerization reaction of each resin and other resins, a product derived from crosslinking reaction of each resin and other resins, a product derived from copolymerizing each resin and other resins or the like.

If not specified, the unsaturated bonds as used herein refer to reactive unsaturated bonds, such as but not limited to unsaturated bonds capable of carrying out crosslinking reaction with other functional groups, such as but not limited to unsaturated C═C double bonds capable of carrying out crosslinking reaction with other functional groups.

The unsaturated C═C double bond as used herein, preferably, includes but is not limited to a vinyl group, a vinylbenzyl group, a (meth)acryloyl group, an allyl group or a combination thereof. The term “vinyl group” is interpreted as including a vinyl group and a vinylidene group. The term “(meth)acryloyl group” is interpreted as including an acryloyl group and a methylacryloyl group.

If not specified, alkyl group, alkenyl group, monomer as used herein are interpreted as including any isomers thereof. For example, propyl group is interpreted as including n-propyl group and isopropyl group.

If not specified, in the present disclosure, “parts by weight” represents the relative parts by weight in the composition, which may be any weight unit, such as but not limited to kilogram, gram, pound or the like. For example, 100 parts by weight of an unsaturated C═C double bond-containing polyphenylene ether resin may represent 100 kilograms of the unsaturated C═C double bond-containing polyphenylene ether resin or 100 pounds of the unsaturated C═C double bond-containing polyphenylene ether resin.

It should be understood that each of the embodiments herein may be arbitrarily combined to form the technical solution of the present disclosure as long as there is no contradiction in the combination of these features.

Examples and embodiments are described in detail below. It should be understood that these examples and embodiments are exemplary only and are not intended to limit the scope and use of the present disclosure. Unless otherwise specified, methods, reagents and conditions adopted in the embodiments are routine methods, reagents and conditions in the field.

The present disclosure discloses a phosphorus-containing compound represented by Formula (1):

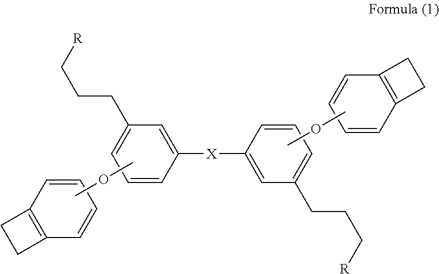

wherein in Formula (1), X is a covalent bond or a C1-C3 alkyl group, such as methyl, ethyl or propyl, each of R is independently a group represented by Formula (2), Formula (3) or Formula (4),

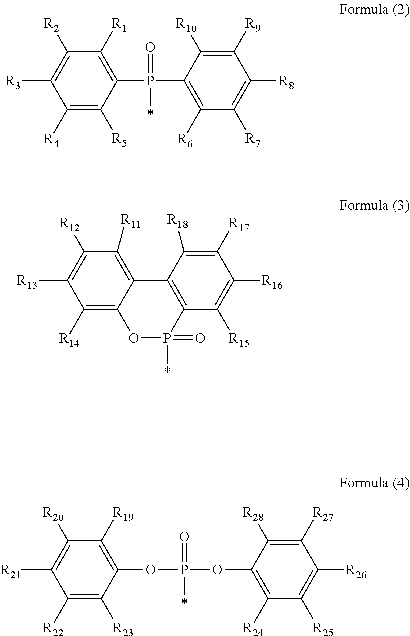

wherein each of R₁ to R₂₈ is independently a hydrogen atom or a C1-C3 alkyl group, such as methyl, ethyl or propyl.

In one embodiment, for example, the phosphorus-containing compound is any one of phosphorus-containing compounds represented by Formula (5) to Formula (9).

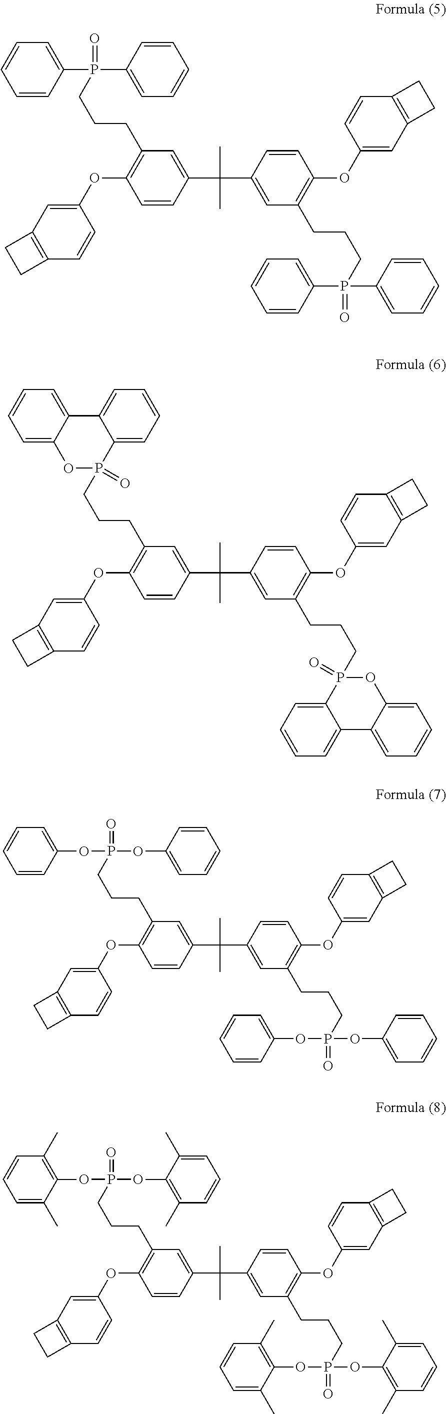 [SMILES: CC(C)(c1ccc(Oc2ccc3c(c2)CC3)c(CCCP(=O)(c2ccccc2)c2ccccc2)c1)c1ccc(Oc2ccc3c(c2)CC3)c(CCCP(=O)(c2ccccc2)c2ccccc2)c1 ; CC(C)(c1ccc(Oc2ccc3c(c2)CC3)c(CCCP2(=O)Oc3ccccc3-c3ccccc32)c1)c1ccc(Oc2ccc3c(c2)CC3)c(CCCP2(=O)Oc3ccccc3-c3ccccc32)c1 ; CC(C)(c1ccc(Oc2ccc3c(c2)CC3)c(CCCP(=O)(Oc2ccccc2)Oc2ccccc2)c1)c1ccc(Oc2ccc3c(c2)CC3)c(CCCP(=O)(Oc2ccccc2)Oc2ccccc2)c1 ; Cc1cccc(C)c1OP(=O)(CCCc1cc(C(C)(C)c2ccc(Oc3ccc4c(c3)CC4)c(CCCP(=O)(Oc3c(C)cccc3C)Oc3c(C)cccc3C)c2)ccc1Oc1ccc2c(c1)CC2)Oc1c(C)cccc1C]

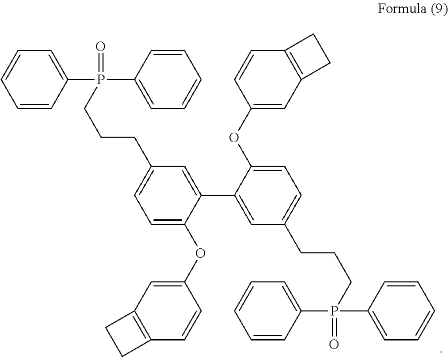 [SMILES: O=P(CCCc1ccc(Oc2ccc3c(c2)CC3)c(-c2cc(CCCP(=O)(c3ccccc3)c3ccccc3)ccc2Oc2ccc3c(c2)CC3)c1)(c1ccccc1)c1ccccc1]

The phosphorus-containing compound represented by Formula (1) may be prepared by various methods known to those skilled in the art. For example, the manufacturing method of the phosphorus-containing compound represented by Formula (1) may comprise the following steps:
step (1): preparing a Grignard reagent of halobenzocyclobutene in a reaction vessel, for example, but not limited to, adding magnesium powder, organic solvent, elemental iodine and bromobenzocyclobutene into a reaction vessel to react and obtain a Grignard reagent of bromobenzocyclobutene;
step (2): reacting diallylbisphenol with one or more of compounds R—H in another reaction vessel to obtain an intermediate compound 1; and
step (3): reacting the Grignard reagent of halobenzocyclobutene with the intermediate compound 1 to obtain the phosphorus-containing compound represented by Formula (1).

The organic solvent in the step (1) comprises, but is not limited to, anhydrous tetrahydrofuran.

The reaction temperature for the step (1) is 0° C. to 100° C.

The reaction time for the step (1) is 1 to 10 hours.

In the step (2), an organic solvent, comprising but not limited to toluene, xylene or a combination thereof, may be further added.

In the step (2), the definition of R of the compound R—H is the same as the definition of R in Formula (1), and H of the compound R—H represents hydrogen atom. The compound R—H comprises but is not limited to diphenylphosphine oxide (DPO), 9,10-dihydro-9-oxa-10-phosphaphenanthrene-10-oxide (DOPO), diphenyl phosphate or bis(2,6-dimethylphenyl)phosphate. The molar ratio of the compound R—H to diallylbisphenol is 2:1 to 3:1.

The reaction temperature for the step (2) is 80° C. to 160° C.

The reaction time for the step (2) is 1 to 6 hours.

The reaction temperature for the step (3) is −20° C. to 120° C.

The reaction time for the step (3) is 3 to 30 hours.

The present disclosure also discloses a resin composition, comprising the following components or a prepolymer thereof,
component (A): 100 parts by weight of an unsaturated C═C double bond-containing polyphenylene ether resin; and
component (B): 15 parts by weight to 90 parts by weight of the phosphorus-containing compound represented by Formula (1);
wherein the prepolymer is obtained from a mixture through prepolymerization, and the mixture comprises at least the component (A) and the component (B).

In one embodiment, for example, with respect to 100 parts by weight of the unsaturated C═C double bond-containing polyphenylene ether resin, the amount of the phosphorus-containing compound represented by Formula (1) may be 15, 25, 40, 50, 80, or 90 parts by weight, and is not limited thereto.

In another embodiment, for example, the resin composition comprises a prepolymer, and the prepolymer is formed from 100 parts by weight of the unsaturated C═C double bond-containing polyphenylene ether resin and 15 parts by weight to 90 parts by weight of the phosphorus-containing compound represented by Formula (1) through prepolymerization. The prepolymer of the present disclosure comprises some residual unsaturated C═C double bonds, and both the conversion rate of the raw material of the reaction and the molecular weight of the prepolymer are in a controlled range. In one embodiment, the residual unsaturated C═C double bonds in the prepolymer may react with other components (such as the unsaturated C═C double bond-containing crosslinking agent in the resin composition), for example, through polymerization or crosslinking reaction. In the present disclosure the presence and the content of the residual unsaturated C═C double bonds in the prepolymer are controlled by controlling the conversion rate of the phosphorus-containing compound represented by Formula (1) and the unsaturated C═C double bond-containing polyphenylene ether resin. The conversion rate of the phosphorus-containing compound represented by Formula (1) and the unsaturated C═C double bond-containing polyphenylene ether resin may be controlled by means known in the field, for example, by a curing accelerator and/or a molecular weight regulator, and the reaction temperature and the reaction time. For example, the conversion rate of the phosphorus-containing compound represented by Formula (1) may be 10% to 99%, preferably 30% to 95%, 50% to 95%, 50% to 90%, or 75% to 90%. For example, the conversion rate of the phosphorus-containing compound represented by Formula (1) being 0% means that the phosphorus-containing compound represented by Formula (1) is not reacted at all, and the prepolymer of the present disclosure cannot be formed. The conversion rate of the phosphorus-containing compound represented by Formula (1) being 100% means that the phosphorus-containing compound represented by Formula (1) is totally reacted, in this case, the prepolymer of the present disclosure cannot be formed either.

For example, the prepolymer of the present disclosure may be prepared by the following method: prepolymerizaing the mixture comprising at least 100 parts by weight of the unsaturated C═C double bond-containing polyphenylene ether resin and 15 parts by weight to 90 parts by weight of the phosphorus-containing compound represented by Formula (1) under an appropriate condition. For example, the prepolymerization may be performed in the presence of a curing accelerator and/or a molecular weight regulator existing. The types of the curing accelerators are described in detail later. In one or more embodiments, the molecular weight regulator includes n-butyl mercaptan, dodecyl mercaptan, mercaptoacetic acid, mercaptopropanoic acid, mercaptoethanol, 2,4-diphenyl-4-methyl-1-pentene, 4,4′-butylidenebis(6-t-butyl-3-methylphenol), 2,2′-methylenebis(4-ethyl-6-t-butylphenol) or a combination thereof. The amounts of the curing accelerator and/or the molecular weight regulator applicable to the present disclosure are not specifically limited and may be independently 0.01 to 5 parts by weight, for example, 0.1 to 3 parts by weight, with respect to a total of 100 parts by weight of the unsaturated C═C double bond-containing polyphenylene ether resin and the phosphorus-containing compound represented by Formula (1), and are not limited thereto. Generally, the unsaturated C═C double bond-containing polyphenylene ether resin and the phosphorus-containing compound represented by Formula (1), and any curing accelerator and/or molecular weight regulator, are dissolved in a solvent for prepolymerization. The solvent may be a solvent conventionally used for polymerization of an unsaturated C═C double bond-containing monomer or oligomer and an unsaturated C═C double bond-containing polyphenylene ether resin, comprising but not limited to toluene. The temperature for prepolymerization is generally greater than room temperature, such as 50° C. to 140° C., preferably 80° C. to 120° C. The reaction time is generally 0.5 to 6 hours, preferably 1 to 4 hours. The reaction is generally performed under stirring. Generally, before reacting, the reaction temperature is raised above room temperature, and after reacting for a while, the temperature is cooled down to room temperature (about 25° C.) to obtain a solution. The solution is filtered using a filter to remove impurities to obtain a prepolymerization product, i.e., the prepolymer obtained from the phosphorus-containing compound represented by Formula (1) and the unsaturated C═C double bond-containing polyphenylene ether resin by prepolymerization.

The unsaturated C═C double bond-containing polyphenylene ether resin applicable to the present disclosure is not particularly limited, may be any one or more of unsaturated C═C double bond-containing polyphenylene ether resins applicable to the production of a prepreg, a resin film, a laminate, or a printed circuit board, and may be any one or more of commercial products, homemade products or a combination thereof, such as but not limited to (meth)acryloyl-containing polyphenylene ether resin, vinylbenzyl-containing polyphenylene ether resin, vinyl-containing polyphenylene ether resin or a combination thereof.

All the unsaturated C═C double bond-containing polyphenylene ether resins of the present disclosure have unsaturated C═C double bonds and a backbone of phenyl ether, wherein the unsaturated C═C double bonds are reactive functional groups, which may be self-polymerized after heated and may perform free radical polymerization with other components containing an unsaturated bond in the resin composition and finally result in crosslinking and curing. The cured products have properties of high heat resistance and low dielectric. Preferably, the unsaturated C═C double bond-containing polyphenylene ether resin includes an unsaturated C═C double bond-containing polyphenylene ether resin with 2,6-dimethyl substitution in its phenylene ether backbone, wherein the methyl groups form steric hindrance to prevent the oxygen atom of the ether group from forming a hydrogen bond or Van der Waals force to absorb moisture, thereby having a lower dielectric property.

In some embodiments, the unsaturated C═C double bond-containing polyphenylene ether resin includes but is not limited to a (meth)acryloyl-containing polyphenylene ether resin with a number average molecular weight of about 1900 to 2300 (such as SA9000, available from Sabic), a vinylbenzyl-containing polyphenylene ether resin with a number average molecular weight of about 1200 (such as OPE-2st 1200, available from Mitsubishi Gas Chemical Co., Inc.), a vinylbenzyl-containing polyphenylene ether resin with a number average molecular weight of about 2200 (such as OPE-2st 2200, available from Mitsubishi Gas Chemical Co., Inc.), a vinylbenzyl-containing polyphenylene ether resin with a number average molecular weight of about 2400 to 2800 (such as vinylbenzyl-containing bisphenol A polyphenylene ether resin), a vinyl-containing polyphenylene ether resin with a number average molecular weight of about 2200 to 3000, or a combination thereof. Among them, the vinyl-containing polyphenylene ether resin may include various polyphenylene ether resins disclosed in US Patent Application Publication No. 20160185904 A1, all of which are incorporated herein by reference in their entirety. Among them, the vinylbenzyl-containing polyphenylene ether resin includes but is not limited to a vinylbenzyl-containing biphenyl polyphenylene ether resin, a vinylbenzyl-containing bisphenol A polyphenylene ether resin or a combination thereof.

For example, in one embodiment, any one of an unsaturated C═C double bond-containing crosslinking agent, an organic silicone resin, a benzoxazine resin, an epoxy resin, a polyester resin, a phenol resin, an amine curing agent, a polyamide, a polyimide, a styrene maleic anhydride, a maleimide resin, a cyanate ester resin, and a maleimide triazine resin, or a combination thereof may be also added to the resin composition of the present disclosure as needed.

In the present disclosure, for example, the unsaturated C═C double bond-containing crosslinking agent may be various unsaturated C═C double bond-containing crosslinking agents known in the field. Specific examples of the unsaturated C═C are any one of bis(vinylphenyl) ethane, bis(vinylbenzyl) ether, divinylbenzene, divinylnaphthalene, divinylbiphenyl, tert-butylstyrene, triallyl isocyanurate, triallyl cyanurate, trivinylcyclochexane, diallyl bisphenol A, styrene, butadiene, decadiene, octadiene, vinyl carbazole, and acrylate ester, or a combination thereof.

If not specified, the amount of the unsaturated C═C double bond-containing crosslinking agent in the resin composition of the present disclosure may be adjusted as needed, for example, but not limited to, with respect to 100 parts by weight of the unsaturated C═C double bond-containing polyphenylene ether resin, the amount of the unsaturated C═C double bond-containing crosslinking agent may be 1 to 20 parts by weight, such as 1 part by weight, 5 parts by weight, 10 parts by weight, 15 parts by weight or 20 parts by weight.

In the present disclosure, for example, the organic silicone resin may be various organic silicone resins known in the field. Specific examples of the organic silicone resin include, but are not limited to, polyalkylsiloxane, polyarylsiloxane, polyalkarylsiloxane, modified polysiloxane or a combination thereof. Preferably, an amino-modified silicone resin is applicable to the organic silicone resin herein, such as but not limited to products KF-8010, X-22-161A, X-22-161B, KF-8012, KF-8008, X-22-9409, and X-22-1660B-3 available from Shin-Etsu Chemical Co., Ltd., products BY-16-853U, BY-16-853, and BY-16-853B available from Toray-Dow corning Co., Ltd., and products XF42-C5742, XF42-C6252, and XF42-C5379 available from Momentive Performance Materials JAPAN LLC, or a combination thereof.

If not specified, the amount of the organic silicone resin in the resin composition of the present disclosure may be adjusted as needed, for example but not limited to, with respect to 100 parts by weight of the unsaturated C═C double bond-containing polyphenylene ether resin, the amount of the organic silicone resin may be 10 to 100 parts by weight, such as 10 parts by weight, 15 parts by weight, 20 parts by weight, 30 parts by weight, 40 parts by weight, 50 parts by weight, 60 parts by weight, 70 parts by weight, 80 parts by weight, 90 parts by weight or 100 parts by weight.

In the present disclosure, for example, the benzoxazine resin may be various benzoxazine resins known in the field. Specific examples of the benzoxazine resin include, but are not limited to, bisphenol A benzoxazine resin, bisphenol F benzoxazine resin, phenolphthalein benzoxazine resin, dicyclopentadiene benzoxazine resin, phosphorus-containing benzoxazine resin, diaminobenzoxazine resin, and phenyl, vinyl or allyl-modified benzoxazine resin. Commercially available products include LZ-8270 (phenolphthalein benzoxazine resin), LZ-8298 (phenolphthalein benzoxazine resin), LZ-8280 (bisphenol F benzoxazine resin) and LZ-8290 (bisphenol A benzoxazine resin) available from Huntsman, or KZH-5031 (vinyl-modified benzoxazine resin) and KZH-5032 (phenyl-modified benzoxazine resin) available from Kolon Industries Inc. Among them, the diaminobenzoxazine resin may be diaminodiphenylmethane benzoxazine resin, diaminodiphenyl ether benzoxazine resin, diaminodiphenyl sulfone benzoxazine resin, diaminodiphenyl sulfide benzoxazine resin, or a combination thereof, but not limited thereto.

If it is not specified, the amount of the benzoxazine resin in the resin composition of the present disclosure may be adjusted according as needed, for example but not limited to, with respect to 100 parts by weight of the unsaturated C═C double bond-containing polyphenylene ether resin, the amount of the benzoxazine resin may be 10 to 100 parts by weight, such as 10 parts by weight, 15 parts by weight, 20 parts by weight, 30 parts by weight, 40 parts by weight, 50 parts by weight, 60 parts by weight, 70 parts by weight, 80 parts by weight, 90 parts by weight or 100 parts by weight.

In the present disclosure, for example, the epoxy resin may be various epoxy resins known in the field. In terms of improving the heat resistance of the resin composition, the epoxy resin described above includes but is not limited to such as bisphenol A epoxy resin, bisphenol F epoxy resin, bisphenol S epoxy resin, bisphenol AD epoxy resin, novolac epoxy resin, trifunctional epoxy resin, tetrafunctional epoxy resin, multifunctional novolac epoxy resin, dicyclopentadiene (DCPD) epoxy resin, phosphorus-containing epoxy resin, p-xylene epoxy resin, naphthalene epoxy resin (such as naphthol epoxy resin), benzofuran epoxy resin, isocyanate-modified epoxy resin, or a combination thereof. Among them, the novolac epoxy resin may be phenol novolac epoxy resin, bisphenol A novolac epoxy resin, bisphenol F novolac epoxy resin, biphenyl novolac epoxy resin, phenol benzaldehyde epoxy resin, phenol aralkyl novolac epoxy resin or o-cresol novolac epoxy resin. Among them, the phosphorus-containing epoxy resin may be DOPO (9,10-dihydro-9-oxa-10-phosphaphenanthrene-10-oxide) epoxy resin, DOPO-HQ epoxy resin or a combination thereof. The DOPO epoxy resin may be selected from one or more of DOPO-containing phenol novolac epoxy resin, DOPO-containing o-cresol novolac epoxy resin and DOPO-containing bisphenol-A novolac epoxy resin. The DOPO-HQ epoxy resin may be selected from one or more of DOPO-HQ-containing phenol novolac epoxy resin, DOPO-HQ-containing o-cresol novolac epoxy resin and DOPO-HQ-containing bisphenol-A novolac epoxy resin, but not limited thereto.

If it is not specified, the amount of the epoxy resin in the resin composition of the present disclosure may be adjusted as needed, for example but not limited to, with respect to 100 parts by weight of the unsaturated C═C double bond-containing polyphenylene ether resin, the amount of the epoxy resin may be 10 to 100 parts by weight, such as 10 parts by weight, 15 parts by weight, 20 parts by weight, 30 parts by weight, 40 parts by weight, 50 parts by weight, 60 parts by weight, 70 parts by weight, 80 parts by weight, 90 parts by weight or 100 parts by weight.

In the present disclosure, for example, the polyester resin may be various polyester resins known in the field. Specific examples of the polyester resin include, but are not limited to, dicyclopentadiene-containing polyester resin, biphenyl-containing polyester resin and naphthalene-containing polyester resin. Specific examples of the polyester resin include, but are not limited to, HPC-8000 or HPC-8150 available from D.I.C. Corporation. If it is not specified, the amount of the polyester resin in the resin composition of the present disclosure may be adjusted as needed, for example but not limited to, with respect to 100 parts by weight of the unsaturated C═C double bond-containing polyphenylene ether resin, the amount of the polyester resin may be 10 to 80 parts by weight, such as 10 parts by weight, 15 parts by weight, 20 parts by weight, 30 parts by weight, 40 parts by weight, 50 parts by weight, 60 parts by weight, 70 parts by weight or 80 parts by weight.

In the present disclosure, for example, the phenol resin may be various phenol resins known in the field. Specific examples of the phenol resin include, but are not limited to, novolac resin or phenoxy resin. Among them, the novolac resin includes phenol novolac resin, o-cresol novolac resin, bisphenol-A novolac resin, naphthol novolac resin, biphenyl novolac resin and dicyclopentadiene phenol resin, but not limited thereto. If it is not specified, the amount of the phenol resin in the resin composition of the present disclosure may be adjusted as needed, for example but not limited to, with respect to 100 parts by weight of the unsaturated C═C double bond-containing polyphenylene ether resin, the amount of the phenol resin may be 10 to 80 parts by weight, such as 10 parts by weight, 15 parts by weight, 20 parts by weight. 30 parts by weight, 40 parts by weight, 50 parts by weight, 60 parts by weight, 70 parts by weight or 80 parts by weight.

In the present disclosure, for example, the amine curing agent may be various amine curing agents known the art. Specific examples of the amine curing agent include, but are not limited to, at least one of diaminodiphenyl sulfone, diaminodiphenyl methane, diaminodiphenyl ether, diaminodiphenyl sulfide and dicyandiamide, or a combination thereof. If it is not specified, the amount of the amine curing agent in the resin composition of the present disclosure may be adjusted as needed, for example but not limited to, with respect to 100 parts by weight of the unsaturated C═C double bond-containing polyphenylene ether resin, the amount of the amine curing agent may be 1 to 15 parts by weight, such as 1 parts by weight, 4 parts by weight, 7.5 parts by weight, 12 parts by weight, or 15 parts by weight.

In the present disclosure, for example, the polyamide may be various polyamides known in the field, including but not limited to various commercially available polyamide resin products.

In the present disclosure, for example, the polyimide may be various polyimides known in the field, including but not limited to various commercially available polyimide resin products.

In the present disclosure, for example, the styrene maleic anhydride may be various styrene maleic anhydrides known in the field, wherein the ratio of the styrene(S) and maleic anhydride (MA) may be 1/1, 2/1, 3/1, 4/1, 6/1, 8/1 or 12/1. Specific examples of the styrene maleic anhydride include styrene maleic anhydride copolymers, such as SMA-1000, SMA-2000, SMA-3000, EF-30, EF-40, EF-60 and EF-80 available from Cray Valley, or styrene maleic anhydride copolymer, such as C400, C500, C700, and C900 available from Polyscope, but not limited thereto.

In the present disclosure, for example, the maleimide resin may be various maleimide resins known in the field. Specific examples of the maleimide resin include but are not limited to 4,4′-diphenylmethane bismaleimide, polyphenylmethane maleimide (also known as oligomer of phenylmethane maleimide), bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl) hexane, N-2,3-xylylmaleimide, N-2,6-xylylmaleimide, N-phenylmaleimide, vinylbenzyl maleimide (VBM), biphenyl-containing maleimide, maleimide resin containing an aliphatic structure with 10 to 50 carbon atoms, or a combination thereof. The maleimide resin is interpreted as also including the modification of these components. The modification includes but is not limited to a prepolymer of diallyl compound and maleimide resin, a prepolymer of diamine and maleimide resin, a prepolymer of multi-functional amine and maleimide resin, a prepolymer of acidic phenol compound and maleimide resin, or a combination thereof.

For example, the maleimide resin may include products such as but not limited to BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000 and BMI-7000H available from Daiwakasei Industry Co., Ltd., BMI-70, and BMI-80 available from K.I Chemical Industry Co., Ltd., or MIR-3000 and MIR-5000 available from Nippon Kayaku.

For example, the maleimide resin containing the aliphatic structure with 10 to 50 carbon atoms (also known as imide-extended maleimide resin) may include various imide-extended maleimide resins disclosed in TW Patent Application Publication No. 200508284A, all of which are incorporated herein by reference in their entirety. The maleimide resin containing an aliphatic long chain structure applicable to the present disclosure may include products such as but not limited to BMI-689, BMI-1400, BMI-1500, BMI-1700, BMI-2500, BMI-3000, BMI-5000 and BMI-6000 available from Designer Molecules Inc.

In the present disclosure, for example, the cyanate ester resin may be various cyanate ester resins known in the field. For example, the cyanate ester resin may be a compound having Ar—O—C≡N structure, wherein Ar may be a substituted or unsubstituted aromatic group. In terms of improving the heat resistance of the resin composition, the specific examples of the cyanate ester resin include, but are not limited to, novolac cyanate ester resin, bisphenol A cyanate ester resin, bisphenol F cyanate ester resin, dicyclopentadiene-containing cyanate ester resin, naphthalene-containing cyanate ester resin, phenolphthalein cyanate ester resin, adamantane cyanate ester resin, fluorene cyanate ester resin or a combination thereof. Among them, the novolac cyanate ester resin may be bisphenol A novolac cyanate ester resin, bisphenol F novolac cyanate ester resin or a combination thereof. For example, the cyanate ester resin may be products such as Primaset PT-15, PT-30S. PT-60S, BA-200, BA-230S, BA-3000S, BTP-2500, BTP-6020S, DT-4000, DT-7000, ULL950S, HTL-300, CE-320, LVT-50, and LeCy available from Lonza.

For example, if it is not specified, the maleimide triazine resin in the resin composition of the present disclosure is not particularly limited, and may be any one or more of maleimide triazine resins applicable to the production of a prepreg, a resin film, a laminate, or a printed circuit board. For example, the maleimide triazine resin may be obtained by polymerizing the cyanate ester resin and the maleimide resin. The maleimide triazine resin may be, but not limited to, obtained by polymerizing bisphenol A cyanate ester resin and maleimide resin, by polymerizing bisphenol F cyanate ester resin and maleimide resin, by polymerizing phenol novolac cyanate ester resin and maleimide resin, or by polymerizing dicyclopentadiene-containing cyanate ester resin and maleimide resin. For example, the maleimide triazine resin may be obtained by polymerizing cyanate ester resin and maleimide resin at any molar ratio. For example, the cyanate ester resin may be 1 to 10 moles, with respect to 1 mole of the maleimide resin. For example, but not limited to, the cyanate ester resin is 1, 2, 4 or 6 moles, with respect to 1 mole of the maleimide resin.

Besides the components, the resin composition of the present disclosure may also further include a curing accelerator, a polymerization inhibitor, an inorganic filler, a surfactant, a coloring agent, a solvent, or a combination thereof, as needed.

For example, the curing accelerator described above may include a catalyst, such as a Lewis base or a Lewis acid. The Lewis base may include one or more of imidazole, boron trifluoride-amine complex, ethyltriphenyl phosphonium chloride, 2-methylimidazole (2 MI), 2-phenyl-1H-imidazole (2PZ), 2-ethyl-4-methylimidazole (2E4MI), triphenylphosphine (TPP) and 4-dimethylaminopyridine (DMAP). The Lewis acid may include metal salt compounds, such as metal salt compounds of manganese, iron, cobalt, nickel, copper and zinc, and metal catalysts, such as zinc octanoate or cobalt octanoate. The curing accelerator described above also includes a curing initiator, such as a peroxide capable of producing free radicals, including but not limited to dicumyl peroxide, t-butyl peroxybenzoate, dibenzoyl peroxide (BPO), 2,5-dimethyl-2,5-di(t-butylperoxy)-3-hexyne (25B) and bis(t-butylperoxyisopropyl)benzene, or a combination thereof. For example, in one embodiment, with respect to 100 parts by weight of the unsaturated C═C double bond-containing polyphenylene ether resin, the resin composition of the present disclosure may also further include 1 parts by weight to 5 parts by weight of the curing accelerator, preferably 1 parts by weight to 4 parts by weight of the curing accelerator, more preferably 0.1 parts by weight to 3.0 parts by weight of the curing accelerator, but not limited thereto.

For example, the polymerization inhibitor described above may include but is not limited to 1,1-diphenyl-2-picrylhydrazyl, methyl acrylonitrile, 2,2,6,6-tetramethylpiperidine-1-oxyl, dithioester, nitroxide-mediated radical, triphenylmethyl radical, metal ion radical, sulfur radical, hydroquinone, 4-methoxyphenol, p-benzoquinone, phenothiazine, β-phenylnaphthylamine, 4-t-butylcatechol, methylene blue, 4,4′-butylidenebis(6-t-butyl-3-methylphenol) and 2,2′-methylenebis(4-ethyl-6-t-butyl phenol), or a combination thereof. For example, the nitroxide-mediated radical described above may include, but is not limited to, nitroxide radicals derived from cyclic hydroxylamines such as 2,2,6,6-substituted piperidine-1-oxyl free radical or 2,2,5,5-substituted pyrrolidine-1-oxyl free radical or the like. Substitutes preferably include alkyl groups with 4 or fewer carbon atoms, such as methyl group or ethyl group. The specific nitroxide radical compound is not limited, and examples include, but are not limited to, 2,2,6,6-tetramethylpiperidine-1-oxyl free radical, 2,2,6,6-tetraethylpiperidine-1-oxyl free radical, 2,2,6,6-tetramethyl-4-oxo-piperidine-1-oxyl free radical, 2,2,5,5-tetramethylpyrrolidine-1-oxyl free radical, 1,1,3,3-tetramethyl-2-isoindoline oxygen radical, N,N-di-tert-butylamine oxygen free radical or the like. The nitroxide radicals may also be replaced by stable radicals such as galvinoxyl radicals. The polymerization inhibitor applicable to the resin composition of the present disclosure may also be products derived from the polymerization inhibitor with its hydrogen atom or atomic group substituted by other atom or atomic group, such as products derived from the polymerization inhibitor with its hydrogen atom substituted by an amino group, a hydroxyl group, a carbonyl group or the like. For example, in one embodiment, with respect to 100 parts by weight of an unsaturated C═C double bond-containing polyphenylene ether resin, the resin composition in the resin composition of the present disclosure may further include 0.001 parts by weight to 20 parts by weight of the polymerization inhibitor, preferably 0.01 parts by weight to 10 parts by weight of the polymerization inhibitor, but not limited thereto.

For example, the inorganic filler may be any one or more of inorganic fillers applicable to the production of a prepreg, a resin film, a laminate, or a printed circuit board. Specific examples of the inorganic filler include, but are not limited to, silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride, zirconium tungstate, petalite, calcined kaolin or a combination thereof. Moreover, the inorganic filler may be spherical, fibrous, plate, particulate, flake or whisker and may be optionally pretreated by a silane coupling agent. For example, in one embodiment, with respect to 100 parts by weight of the unsaturated C═C double bond-containing polyphenylene ether resin, the resin composition of the present disclosure may further include 10 parts by weight to 300 parts by weight of the inorganic filler, preferably 30 parts by weight to 250 parts by weight of the inorganic filler, more preferably 60 parts by weight to 200 parts by weight of the inorganic filler, but not limited thereto.

For example, the type of the surfactant described above is not particularly limited. The purpose of the surfactant used herein is to make the inorganic filler uniformly distributed in the resin composition.

For example, the coloring agent described above may include but is not limited to dye or pigment.

For example, the solvent applicable to the resin composition of the present disclosure is not particularly limited, and may be any solvent applicable to dissolving the resin composition of the present disclosure, including, but not limited to, methanol, ethanol, ethylene glycol monomethyl ether, acetone, butanone (also known as methyl ethyl ketone), methyl isobutyl ketone, cyclohexanone, toluene, xylene, methoxyethyl acetate, ethoxyethyl acetate, propoxyethyl acetate, ethyl acetate, dimethylformamide, dimethylacetamide, propylene glycol methyl ether acetate, or mixed solvent thereof. The amount of the solvent is for the purpose of adjusting the solid content of the resin composition to a suitable range. For example, in one embodiment, the solvent is added at an additive amount to adjust the solid content of the resin composition to 50 to 85%, but not limited thereto.

The resin composition of each embodiment may be made into various articles, such as the elements applicable to various electronic products, including, but not limited to, a prepreg, a resin film, a laminate or a printed circuit board.

For example, the resin composition of each embodiment of the present disclosure may be made into a prepreg, which includes a reinforcement material and a layered structure disposed thereon. The layered structure is obtained by heating the resin composition at high temperature to a semi-cured state (B-stage). The baking temperature for making the prepreg is between 120° C. and 180° C., preferably between 120° C. and 160° C. The reinforcement material may be any one of fiber material, woven fabric, and non-woven fabric, and the woven fabric preferably includes fiberglass fabrics. Types of fiberglass fabrics are not particularly limited and may be any fiberglass fabrics for printed circuit boards, such as E-glass fiber fabric, D-glass fiber fabric, S-glass fiber fabric. T-glass fiber fabric, L-glass fiber fabric, Q-glass fiber fabric or QL-glass fiber fabric (a glass fiber fabric with a mixed structure made from Q-glass fiber fabric and L-glass fiber fabric). Types of fiberglass include yarns and rovings, in spread form or standard form. The shape of the end surface includes a circular or flat shape. The non-woven fabric preferably includes liquid crystal resin non-woven fabric, such as polyester non-woven fabric, polyurethane non-woven fabric or the like, and not limited thereto. The woven fabric may also include liquid crystal resin woven fabric, such as polyester woven fabric or polyurethane woven fabric or the like, and not limited thereto. The reinforcement materials may increase the mechanical strength of the prepreg. In one preferable embodiment, the reinforcement materials may be optionally pretreated by a silane coupling agent. The prepreg may be further heated and cured to the C-stage to form an insulation layer.

For example, the resin composition of each embodiment of the present disclosure may be made into a resin film, which is obtained by heating and baking the resin composition to a semi-cured state. The resin composition may be optionally coated on a polyethylene terephthalate film (PET film), polyimide film (PI film), copper foil or adhesive copper foil, followed by heating and baking to a semi-cured state so as to make the resin composition form into a resin film.

For example, the resin composition of the present disclosure may be made into various laminates, including at least two metal foils and at least one insulation layer disposed between the two metal foils. The insulation layer may be obtained by curing the resin composition at high temperature and high pressure to the C-stage. The suitable curing temperature is, for example, between 190° C. and 220° C., preferably between 200° C. and 210° C., and the curing time is 90 to 180 minutes, preferably 120 to 150 minutes. The insulation layer may be obtained by curing the prepreg or resin film. The material of the metal foil may be copper, aluminum, nickel, platinum, silver, gold or alloy thereof, such as a copper foil. In a preferable embodiment, the laminate is a copper-clad laminate.

In one embodiment, the laminate may be further processed by circuit processing to obtain a printed circuit board.

One of the production method of the printed circuit board of the present disclosure may be as the following. A double-sided copper-clad laminate (such as product EM-827, available from Elite Material Co., Ltd.) with a thickness of 28 mil and having a 1 ounce HTE (High Temperature Elongation) copper foil may be provided and subject to drilling and electroplating so as to form electrical conduction between the top layer copper foil and the bottom layer copper foil. Then the top layer copper foil and the bottom layer copper foil are etched to form an inner layer circuit board. Then brown oxidation and roughening are performed on the inner layer circuit board to form uneven structures on the surface to increase roughness. Next, a copper foil, the prepreg, the inner layer circuit board, the prepreg, and a copper foil are sequentially stacked and then heated at 190° C. to 220° C. for 90 to 180 minutes by a vacuum lamination apparatus to cure the insulation layer material of the prepreg. Next, black oxidation, drilling, copper plating and other circuit board processes known in the field are performed on the outmost copper foil to obtain the printed circuit board.

In one or more embodiments, the resin composition of the present disclosure and various articles made therefrom may preferably have at least one of the following properties:
a glass transition temperature as measured by reference to IPC-TM-650 2.4.24.4 of greater than or equal to 240° C., such as between 240° C. and 277° C.;
a dielectric constant at 10 GHz as measured by reference to JISC2565 of less than or equal to 3.20, such as between 3.05 and 3.20;
a dissipation factor at 10 GHz as measured by reference to JISC2565 of less than or equal to 0.0020, such as between 0.0017 and 0.0020;
a flame retardancy as measured by reference to UL94 rating of V0;
a percent thermal expansion at Z-axis as measured by reference to IPC-TM-650 2.4.24.5 of less than or equal to 1.5%, such as between 0.6% and 1.5%;
no delamination occurs after subjecting the article to a heat resistance after moisture absorption test by reference to IPC-TM-650 2.6.16.1 and IPC-TM-650 2.4.23;
a copper foil peeling strength as measured by reference to IPC-TM-650 2.4.8 of greater than or equal to 3.2 lb/in, such as between 3.2 lb/in and 4.7 lb/in.

In the present disclosure, the property tests of the examples and comparative examples are performed by samples (specimens) prepared as described below, and are tested under specific conditions.

### 1. Prepreg:

The resin compositions respectively selected from the examples or comparative examples are mixed uniformly to form varnish. The varnish is loaded into an impregnation tank, and the fiberglass fabric (such as 2116 L-glass fiber fabric, 1080 L-glass fiber fabric, or 1078 L-glass fiber fabric, all available from Asahi) is then immersed into the impregnation tank described above to adhere the resin composition onto the fiberglass fabric, followed by heating at 150° C. to 170° C. to a semi-cured stage (B-Stage) to obtain a prepreg with a resin content of about 53%.

### 2. Copper-Clad Laminate (8-Ply, Formed by Lamination of Eight Prepregs):

Two HVLP copper foils with a thickness of 18 μm and eight prepregs, with a resin content of about 53% for each, obtained from 2116 L-glass fiber fabrics impregnated with each specimen (each example or comparative example) are prepared and stacked in the order of one HVLP copper foil, eight prepregs and one HVLP copper foil, followed by lamination under vacuum at 420 psi and 200° C. for 2 hours to form a copper-clad laminate. The eight prepregs stacked with each other are cured and formed into an insulation layer between the two copper foils, and the insulation layer has a resin content of about 53%.

### 3. Copper-Free Laminate (8-Ply, Formed by Lamination of Eight Prepregs):

The copper-clad laminate (8-ply) described above is etched to remove two copper foils to obtain a Copper-free laminate (8-ply) which is formed by laminating eight prepregs and has a resin content of about 53%.

### 4. Copper-Free Laminate (2-Ply, Formed by Lamination of Two Prepregs):

Two HVLP copper foils with a thickness of 18 μm and two prepregs obtained from 1080 L-glass fiber fabrics impregnated with each specimen (each example or comparative example) are prepared and stacked in the order of one copper foil, two prepregs and one copper foil, followed by lamination under vacuum at 420 psi and 200° C. for 2 hours to form a copper-clad laminate (2-ply, formed by lamination of two prepregs). Next, the copper-clad laminate (2-ply) described above is etched to remove the copper foils on both sides to obtain a Copper-free laminate (2-ply), which is formed by laminating two prepregs and has a resin content of about 70%.

Each testing method and the properties are described below.

### 1. Glass Transition Temperature (Tg)

The Copper-free laminate (8-ply) is selected as a specimen. A dynamic mechanical analyzer (DMA) is used by reference to IPC-TM-650 2.4.24.4 to measure the glass transition temperature (in ° C.) of each specimen. Temperature interval during the measurement was set at 50 to 400° C. with a temperature increasing rate of 2° C./minute. The higher the glass transition temperature, the better it is.

### 2. Dielectric Constant (Dk) and Dissipation Factor (Df)

The Copper-free laminate (2-ply) is selected as a specimen. A microwave dielectrometer available from AET Corp. is used by reference to JISC2565 to measure each specimen at 10 GHz at room temperature (about 25° C.). Lower dielectric constant and dissipation factor represent better dielectric properties of the specimen. At a frequency of 10 GHz, for a Df value of less than 0.005, a difference in Df value of greater than or equal to 0.0001 represents a significant difference between dissipation factors of different laminates (i.e. significant technical difficulty is present).

### 3. Flame Retardancy

The Copper-free laminate (8-ply) (125 mm×13 mm) is selected as a specimen. The flame retardancy is measured by reference to UL94, and the results are represented by V0, V1, or V2, wherein the flame retardancy of V0 is better than the flame retardancy of V1, and the flame retardancy of V1 is better than the flame retardancy of V2. It is the worst flame retardancy when the specimen is completely burned.

### 4. Percent Thermal Expansion at Z-Axis (Z-PTE)

The Copper-free laminate (8-ply) is selected as a specimen. Thermal mechanical analysis (TMA) is performed on the specimen. The specimens are heated from 50 to 260° C. at a temperature increasing rate of 10° C./minute. The percent thermal expansion (i.e., ratio of thermal expansion) at Z-axis (in %) of each specimen is measured by reference to IPC-TM-650 2.4.24.5 between 50° C. and 260° C. The lower the percent thermal expansion at Z-axis, the better it is. In terms of the copper-clad laminate with percent thermal expansion at Z-axis below 2.0%, a difference in percent thermal expansion at Z-axis of greater than or equal to 0.1% represents a significant difference.

### 5. Pressure Cooking Test (PCT)

The Copper-free laminate (8-ply) is selected as a specimen. By reference to IPC-TM-650 2.6.16.1, the specimen was subject to the pressure cooking test for 3 hours of moisture absorption (at a temperature of 121° C. and a relative humidity of 100%), and then immersed into a solder pot with a constant temperature of 288° C. for 20 seconds to see if any delamination occurs by reference to IPC-TM-650 2.4.23. The occurrence of delamination means failing the test, and no occurrence of delamination means passing the test. “O” means there is no delamination, and “X” means there is delamination in the test. There are 3 specimens in each group of the test. One “X” means that one of the three specimens has delamination; two “X” means that two of the three specimens have delamination; and three “X” means that all of the three specimens have delamination. For example, an interlayer peeling between insulating layers can be called delamination. Interlayer peeling refers to the phenomenon of blistering separation between any layers of the laminate.

### 6. Copper Foil Peeling Strength (P/S)

The copper-clad laminate (8-ply) is cut into a rectangular specimen with a width of 24 mm and a length greater than 60 mm, and then is etched to remove the copper foil on the surface and leave a strip of copper foil with a width of 3.18 mm and a length greater than 60 mm. The specimen is tested by using a tensile strength tester by reference to IPC-TM-650 2.4.8 at room temperature (about 25° C.) to measure the force (lb/in) required to pull off the copper foil from the surface of the insulating layer of the laminate.

The raw materials described below are used to prepare the resin compositions of the examples and the comparative examples of the present disclosure according to the amount disclosed in Table 1 to Table 3, and are further made into various specimens.

The chemical raw materials used in the examples and the comparative examples of the present disclosure as described below:

Phosphorus-containing compounds P1˜P5 represented by Formula (1): prepared by Applicant and described in detail below.

Prepolymer Y1˜Y3: prepared by Applicant and described in detail below.

Compound V1: prepared by Applicant and described in detail below.

Compound D1 having the formula below: prepared by Applicant.

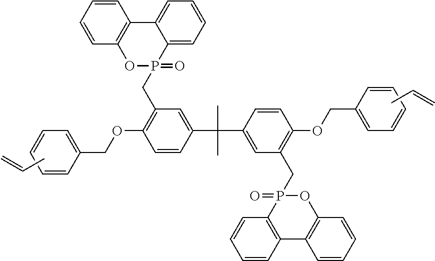

Compound D2 having the formula below: prepared by Applicant.

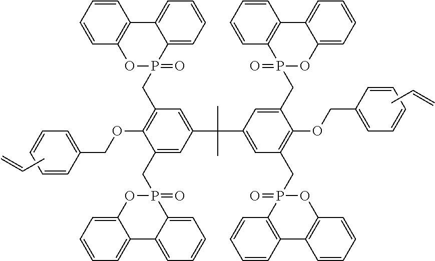

Compound D3 having the formula below: prepared by Applicant.

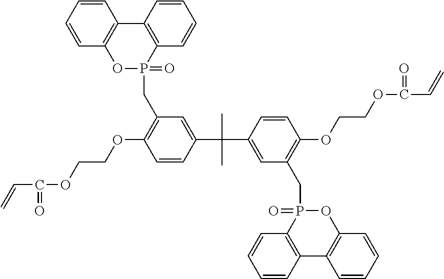 [SMILES: C=CC(=O)OCCOc1ccc(C(C)(C)c2ccc(OCCOC(=O)C=C)c(CP3(=O)Oc4ccccc4-c4ccccc43)c2)cc1CP1(=O)Oc2ccccc2-c2ccccc21]

Compound D4 having the formula below: prepared by Applicant.

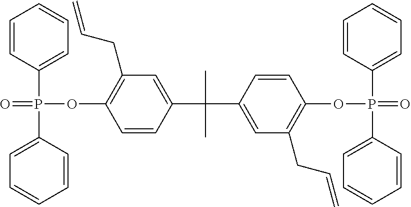 [SMILES: C=CCc1cc(C(C)(C)c2ccc(OP(=O)(c3ccccc3)c3ccccc3)c(CC=C)c2)ccc1OP(=O)(c1ccccc1)c1ccccc1]

SA9000: methylacryloyl-containing polyphenylene ether resin with Mn of about 1900 to 2300, available from Sabic.

OPE-2st 1200: vinylbenzyl-containing polyphenylene ether resin with Mn of about 1200, available from Mitsubishi Gas Chemical Co., Inc.

OPE-2st 2200: vinylbenzyl-containing polyphenylene ether resin with Mn of about 2200, available from Mitsubishi Gas Chemical Co., Inc.

DABPA: diallyl bisphenol A, available from Laizhou City Laiyu Chemical Co., Ltd.

4-bromobenzocyclobutene: available from Shanghai Haohong Biomedical Technology Co., Ltd.

DPO: diphenylphosphine oxide, available from Peking J&K Scientific Ltd.

DVB: divinylbenzene, available from Shanghai Macklin Biochemical Co., Ltd.

BVPE: bis(vinylphenyl) ethane, available from Linchuan Chemical Co., Ltd.

25B: 2,5-dimethyl-2,5-di(t-butylperoxy)-3-hexyne, available from NOF Corporation.

SC-2500 SVJ: spherical silica pre-treated by a silane coupling agent, available from Admatechs.

Toluene: available from China Petrochemical Corporation. The content is indicated by “proper amount”, which represents the amount of the toluene is adjusted such that the resin composition has a solid content of 60% to 68% (solid content, S/C=60% to 68%).

### Preparation Example 1: Phosphorus-Containing Compound P1

S1: Under N₂ protection, 6 g (0.25 mole) of magnesium powder, 500 mL of anhydrous tetrahydrofuran and 0.1 g of elemental iodine are added into a 1000 mL three-necked flask, and 36.6 g (0.2 mole) of 4-bromobenzocyclobutene is dropwise added thereto under slow stirring. The solution is heated to 80° C., followed by refluxing and stirring for 2 hours to obtain a Grignard reagent of 4-bromobenzocyclobutene.
S2: Under N₂ protection, 30.8 g (0.1 mole) of DABPA, 40.4 g (0.2 mole) of DPO and 50 mL of xylene are added into another 1000 mL three-necked flask, followed by stirring at 140° C. for 4 hours to obtain a solution of an intermediate compound. The solution is cooled down to room temperature, and the Grignard reagent of 4-bromobenzocyclobutene prepared in the step 1 (S1) is dropwise slowly added thereto in an iced water bath within about 2 hours. After dropwise addition, the solution is stirred for 8 hours, and then heated to 40° C. and stirred for 2 hours. The product is distilled under reduced pressure, followed by washing, filtering, and drying to obtain the phosphorus-containing compound P1, as illustrated in Formula (5).

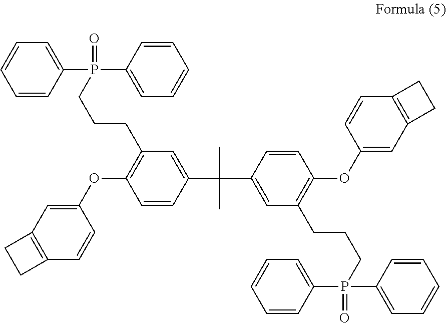 [SMILES: CC(C)(c1ccc(Oc2ccc3c(c2)CC3)c(CCCP(=O)(c2ccccc2)c2ccccc2)c1)c1ccc(Oc2ccc3c(c2)CC3)c(CCCP(=O)(c2ccccc2)c2ccccc2)c1]

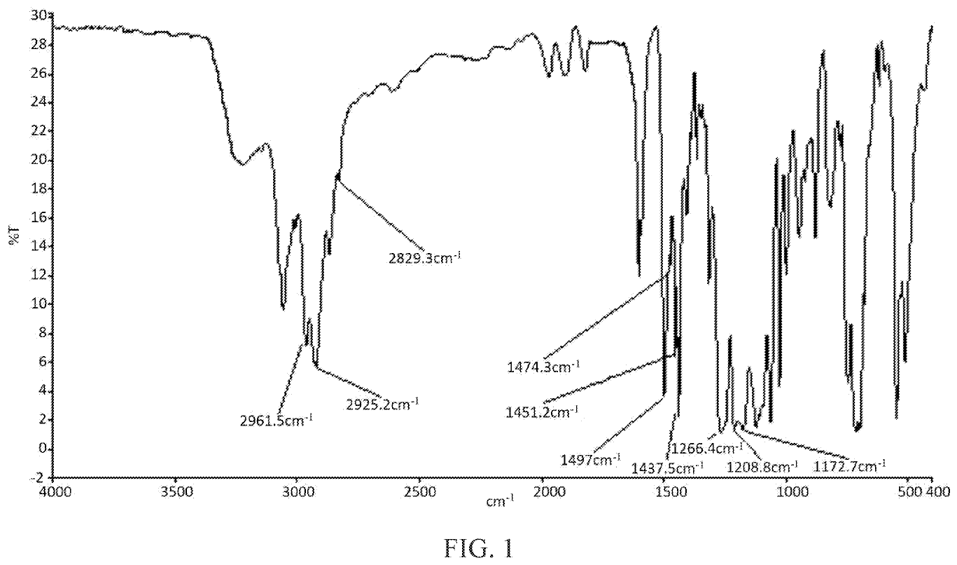

The phosphorus-containing compound P1 obtained in Preparation Example 1 is analyzed by Fourier transform infrared spectroscopy (FTIR), and the result is shown in FIG. 1. The FTIR spectrum reveals peaks indicative of the stretching vibration of C—H of methyl group and methylene group at 2961.5 cm⁻¹ and 2925.2 cm⁻¹; and 949 cm⁻¹, 1185 cm⁻¹ correspond to the P—H bond characteristic absorption peak and P═O double bond stretching vibration peak in DPO, respectively, P—H bond disappears after DPO and DABPA undergo an addition reaction to generate P—C bond. Therefore, the characteristic peak at 949 cm⁻¹ disappears while the characteristic peak of P═O migrates to 1172.7 cm⁻¹. 3445 cm⁻¹ correspond to the O—H stretching vibration absorption peak of DABPA, after the reaction of 4-bromobenzocyclobutene with DABPA, this peak disappeared completely, and the peaks indicative of the stretching vibration of aryl ether bond at 1266.4 cm⁻¹ and the stretching vibration of C—H on the methylene group in the four-membered ring of benzocyclobutene at 2829 cm⁻¹ appear. The peaks at 1400 to 1500 cm⁻¹ are indicative of the characteristic absorption of the benzene ring, wherein the peak at 1437.5 cm⁻¹ is indicative of the characteristic absorption of the benzene ring in DPO, and the peak at 1474.3 cm⁻¹ is indicative of the characteristic absorption of the benzene ring of benzocyclobutene. This proves that the phosphorus-containing compound P1 is successfully synthesized.

### Preparation Example 2: Phosphorus-Containing Compound P2

S1: Under N₂ protection, 6 g (0.25 mole) of magnesium powder, 500 mL of anhydrous tetrahydrofuran and 0.1 g of elemental iodine are added into a 1000 mL three-necked flask, and 36.6 g (0.2 mole) of 4-bromobenzocyclobutene is dropwise added thereto under slow stirring. The solution is heated to 80° C., followed by refluxing and stirring for 2 hours to obtain a Grignard reagent of 4-bromobenzocyclobutene.
S2: Under N₂ protection, 30.8 g (0.1 mole) of DABPA, 43.2 g (0.2 mole) of DOPO and 50 mL of xylene are added into another 1000 mL three-necked flask, followed by stirring at 145° C. for 4.5 hours to obtain a solution of an intermediate compound. The solution is cooled down to room temperature, and the Grignard reagent of 4-bromobenzocyclobutene prepared in the step 1 (S1) is dropwise slowly added thereto in an iced water bath within about 2 hours. After dropwise addition, the solution is stirred for 8 hours, and then heated to 40° C. and stirred for 3 hours. The product is distilled under reduced pressure, followed by washing, filtering, and drying to obtain the phosphorus-containing compound P2, as illustrated in Formula (6).

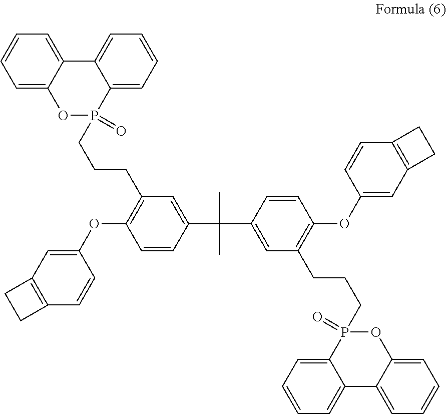 [SMILES: CC(C)(c1ccc(Oc2ccc3c(c2)CC3)c(CCCP2(=O)Oc3ccccc3-c3ccccc32)c1)c1ccc(Oc2ccc3c(c2)CC3)c(CCCP2(=O)Oc3ccccc3-c3ccccc32)c1]

### Preparation Example 3: Phosphorus-Containing Compound P3

S1: Under N₂ protection, 6 g (0.25 mole) of magnesium powder, 500 mL of anhydrous tetrahydrofuran and 0.1 g of elemental iodine are added into a 1000 mL three-necked flask, and 36.6 g (0.2 mole) of 4-bromobenzocyclobutene is dropwise added thereto under slow stirring. The solution is heated to 80° C., followed by refluxing and stirring for 2 hours to obtain a Grignard reagent of 4-bromobenzocyclobutene.
S2: Under N₂ protection, 30.8 g (0.1 mole) of DABPA, 46.8 g (0.2 mole) of diphenyl phosphate and 50 mL of xylene are added into another 1000 mL three-necked flask, followed by stirring at 150° C. for 4 hours to obtain a solution of an intermediate compound. The solution is cooled down to room temperature, and the Grignard reagent of 4-bromobenzocyclobutene prepared in the step 1 (S1) is dropwise slowly added thereto in an iced water bath within about 2 hours. After dropwise addition, the solution is stirred for 8 hours, and then heated to 45° C. and stirred for 3 hours. The product is distilled under reduced pressure, followed by washing, filtering, and drying to obtain the phosphorus-containing compound P3, as represented by Formula (7).

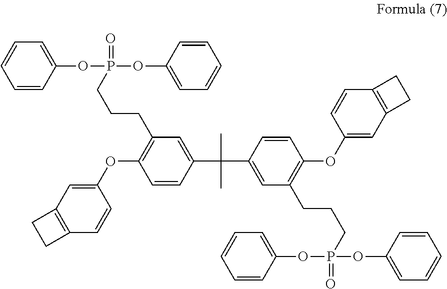 [SMILES: CC(C)(c1ccc(Oc2ccc3c(c2)CC3)c(CCCP(=O)(Oc2ccccc2)Oc2ccccc2)c1)c1ccc(Oc2ccc3c(c2)CC3)c(CCCP(=O)(Oc2ccccc2)Oc2ccccc2)c1]

### Preparation Example 4: Phosphorus-Containing Compound P4

S1: Under N₂ protection, 6 g (0.25 mole) of magnesium powder, 500 mL of anhydrous tetrahydrofuran and 0.1 g of elemental iodine are added into a 1000 mL three-necked flask, and 36.6 g (0.2 mole) of 4-bromobenzocyclobutene is dropwise added thereto under slow stirring. The solution is heated to 80° C., followed by refluxing and stirring for 2 hours to obtain a Grignard reagent of 4-bromobenzocyclobutene.
S2: Under N₂ protection, 30.8 g (0.1 mole) of DABPA, 58.1 g (0.2 mole) of bis(2,6-dimethylphenyl)phosphate and 50 mL of xylene are added into another 1000 mL three-necked flask, followed by stirring at 150° C. for 4 hours to obtain a solution of an intermediate compound. The solution is cooled down to room temperature, and the Grignard reagent of 4-bromobenzocyclobutene prepared in the step 1 (S1) is dropwise slowly added thereto in an iced water bath within about 2 hours. After dropwise addition, the solution is stirred for 10 hours, and then heated to 55° C. and stirred for 3 hours. The product is distilled under reduced pressure, followed by washing, filtering, and drying to obtain the phosphorus-containing compound P4, as represented by Formula (8).

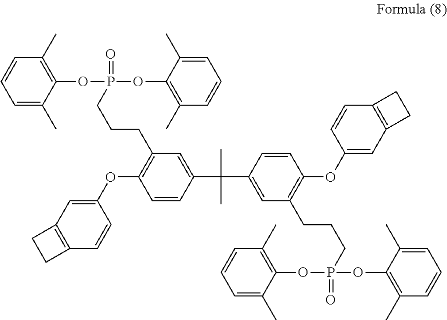 [SMILES: Cc1cccc(C)c1OP(=O)(CCCc1cc(C(C)(C)c2ccc(Oc3ccc4c(c3)CC4)c(CCCP(=O)(Oc3c(C)cccc3C)Oc3c(C)cccc3C)c2)ccc1Oc1ccc2c(c1)CC2)Oc1c(C)cccc1C]

### Preparation Example 5: Phosphorus-Containing Compound P5

S1: Under N₂ protection, 6 g (0.25 mole) of magnesium powder, 500 mL of anhydrous tetrahydrofuran and 0.1 g of elemental iodine are added into a 1000 mL three-necked flask, and 36.6 g (0.2 mole) of 4-bromobenzocyclobutene is dropwise added thereto under slow stirring. The solution is heated to 80° C., followed by refluxing and stirring for 2 hours to obtain a Grignard reagent of 4-bromobenzocyclobutene.
S2: Under N₂ protection, 26.6 g (0.1 mole) of 5,5′-diallyl-2,2′-biphenyldiol, 40.4 g (0.2 mole) of DPO and 50 mL of xylene are added into another 1000 mL three-necked flask, followed by stirring at 140° C. for 4.5 hours to obtain a solution of an intermediate compound. The solution is cooled down to room temperature, and the Grignard reagent of 4-bromobenzocyclobutene prepared in the step 1 (S1) is dropwise slowly added thereto in an iced water bath within about 2 hours. After dropwise addition, the solution is stirred for 10 hours, and then heated to 50° C. and stirred for 4 hours. The product is distilled under reduced pressure, followed by washing, filtering, and drying to obtain the phosphorus-containing compound P5, as represented by Formula (9).

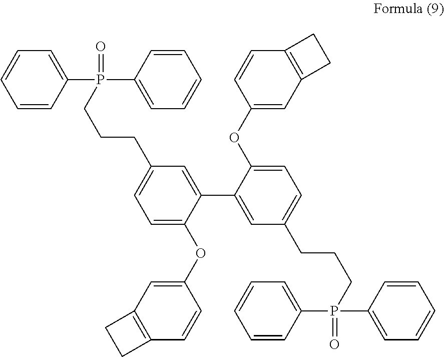 [SMILES: O=P(CCCc1ccc(Oc2ccc3c(c2)CC3)c(-c2cc(CCCP(=O)(c3ccccc3)c3ccccc3)ccc2Oc2ccc3c(c2)CC3)c1)(c1ccccc1)c1ccccc1]

### Preparation Example 6: Prepolymer Y1

100 parts by weight of SA9000, 15 parts by weight of P1 and 110 parts by weight of toluene are added into a Schlenk flask and dissolved, and then 1 part by weight of a curing accelerator 25B is added thereto. The system is vacuumed and purged with nitrogen gas under liquid nitrogen, and the process is repeated three times to remove the oxygen in the system. The system is heated to 120° C. for 2 hours, followed by cooling down, filtering and purifying to obtain the self-made prepolymer Y1 with a solid content of 100%, and the conversion rate of the self-made prepolymer Y1 is 10% to 99%.

### Preparation Example 7: Prepolymer Y2

60 parts by weight of SA9000, 10 parts by weight of OPE-2st 1200, 30 parts by weight of OPE-2st 2200, 20 parts by weight of P1, 10 parts by weight of P2, 10 parts by weight of P3, 10 parts by weight of P4 and 110 parts by weight of toluene are added into a Schlenk flask and dissolved, and then 0.1 parts by weight of a curing accelerator 25B is added thereto. The system is vacuumed and purged with nitrogen gas under liquid nitrogen, and the process is repeated three times to remove the oxygen in the system. The system is heated to 120° C. for 2 hours, followed by cooling down, filtered purifying to obtain self-made prepolymer Y2 with a solid content of 100%, and the conversion rate of the self-made prepolymer Y2 is 10% to 99%.

### Preparation Example 8: Prepolymer Y3

100 parts by weight of SA9000, 90 parts by weight of P1 and 110 parts by weight of toluene are added into Schlenk flask and dissolved, and then 3 parts by weight of a curing accelerator 25B is added thereto. The system is vacuumed and purged with nitrogen gas under liquid nitrogen, and the process is repeated three times to remove the oxygen in the system. The system is heated to 120° C. for 2 hours, followed by cooling down, filtered purifying to obtain self-made prepolymer Y3 with a solid content of 100%, and the conversion rate of the self-made prepolymer Y3 is 10% to 99%.

### Preparation Example 9: Compound V1

S1: Under N₂ protection, 6 g (0.25 mole) of magnesium powder, 500 mL of anhydrous tetrahydrofuran and 0.1 g of elemental iodine are added into a 1000 mL three-necked flask, and 36.6 g (0.2 mole) of 4-bromobenzocyclobutene is dropwise added thereto under slow stirring. The solution is heated to 80° C., followed by refluxing and stirring for 2 hours to obtain a Grignard reagent of 4-bromobenzocyclobutene.
S2: Under N₂ protection, 30.8 g (0.1 mole) of DABPA is added into another 1000 mL three-necked flask, and the Grignard reagent of 4-bromobenzocyclobutene prepared in the step 1 (S1) is dropwise slowly added thereto in an iced water bath within about 2 hours. After dropwise addition, the solution is stirred for 8 hours, and then heated to 40° C. and stirred for 2 hours. The product is distilled under reduced pressure, followed by washing, filtering, and drying to obtain the final product V1.

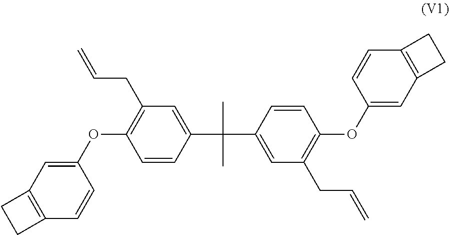 [SMILES: C=CCc1cc(C(C)(C)c2ccc(Oc3ccc4c(c3)CC4)c(CC=C)c2)ccc1Oc1ccc2c(c1)CC2]

The contents of the resin composition (in part by weight) of the examples and the comparative examples and the testing results of the properties of specimens are illustrated in Table 1 to Table 3.

TABLE 1
The contents of the resin composition (in part by weight) of Examples E1 to
E7 and the testing results of the properties of articles made therefrom.

| component | | E1 | E2 | E3 | E4 | E5 | E6 | E7 |
|---|---|---|---|---|---|---|---|---|
| unsaturated C═C double | SA9000 | 100 | 100 | 100 | 100 | 100 | 100 | 100 |
| bond-containing | OPE-2st | — | — | — | — | — | — | — |
| polyphenylene ether | 1200 | | | | | | | |
| resin | OPE-2st | — | — | — | — | — | — | — |
| | 2200 | | | | | | | |
| phosphorus-containing | P1 | 40 | — | — | — | — | — | — |
| compound represented | P2 | — | 40 | — | — | — | 15 | 80 |
| by Formula (1) | P3 | — | — | 40 | — | — | — | — |
| | P4 | — | — | — | 40 | — | — | — |
| | P5 | — | — | — | — | 40 | — | — |
| prepolymer Y1 | | — | — | — | — | — | — | — |
| prepolymer Y2 | | — | — | — | — | — | — | — |
| prepolymer Y3 | | — | — | — | — | — | — | — |
| V1 | | — | — | — | — | — | — | — |
| DABPA | | — | — | — | — | — | — | — |
| 4-bromobenzocyclobutene | | — | — | — | — | — | — | — |
| DPO | | — | — | — | — | — | — | — |
| D1 | | — | — | — | — | — | — | — |
| D2 | | — | — | — | — | — | — | — |
| D3 | | — | — | — | — | — | — | — |
| D4 | | — | — | — | — | — | — | — |
| unsaturated C═C double | DVB | — | — | — | — | — | — | — |
| bond-containing | BVPE | — | — | — | — | — | — | — |
| crosslinking agent | | | | | | | | |
| curing accelerator | 25B | 1 | 1 | 1 | 1 | 1 | 1 | 1 |
| inorganic filler | SC2500- | 150 | 150 | 150 | 150 | 150 | 150 | 150 |
| | SVJ | | | | | | | |
| solvent | toluene | PA | PA | PA | PA | PA | PA | PA |
| property | unit | E1 | E2 | E3 | E4 | E5 | E6 | E7 |
| Tg | ° C. | 260 | 256 | 258 | 251 | 252 | 240 | 265 |
| Dk | / | 3.10 | 3.12 | 3.15 | 3.05 | 3.14 | 3.20 | 3.05 |
| Df | / | 0.0019 | 0.0020 | 0.0020 | 0.0017 | 0.0020 | 0.0020 | 0.0017 |
| flame retardancy | / | V0 | V0 | V0 | V0 | V0 | V0 | V0 |
| Z-PTE | % | 0.9 | 1.0 | 1.0 | 1.2 | 1.0 | 1.5 | 0.8 |
| PCT | / | ◯◯◯ | ◯◯◯ | ◯◯◯ | ◯◯◯ | ◯◯◯ | ◯◯◯ | ◯◯◯ |
| P/S | lb/in | 4.2 | 4.0 | 3.9 | 3.7 | 3.8 | 4.6 | 3.5 |

(PA represents proper amount.)

TABLE 2
The contents of the resin composition (in part by weight) of Examples E8 to
E13 and the testing results of the properties of articles made therefrom.

| component | | E8 | E9 | E10 | E11 | E12 | E13 |
|---|---|---|---|---|---|---|---|
| unsaturated C═C double | SA9000 | 100 | 60 | 50 | — | — | — |
| bond-containing | OPE-2st | — | 10 | 25 | — | — | — |
| polyphenylene ether | 1200 | | | | | | |
| resin | OPE-2st | — | 30 | 25 | — | — | — |
| | 2200 | | | | | | |
| phosphorus-containing | P1 | 90 | 20 | 15 | — | — | — |
| compound represented | P2 | — | 10 | — | — | — | — |
| by Formula (1) | P3 | — | 10 | — | — | — | — |
| | P4 | — | 10 | 5 | — | — | — |
| | P5 | — | — | 5 | — | — | — |
| prepolymer Y1 | | — | — | — | 115 | — | — |
| prepolymer Y2 | | — | — | — | — | 150 | — |
| prepolymer Y3 | | — | — | — | — | — | 190 |
| V1 | | — | — | — | — | — | — |
| DABPA | | — | — | — | — | — | — |
| 4-bromobenzocyclobutene | | — | — | — | — | — | — |
| DPO | | — | — | — | — | — | — |
| D1 | | — | — | — | — | — | — |
| D2 | | — | — | — | — | — | — |
| D3 | | — | — | — | — | — | — |
| D4 | | — | — | — | — | — | — |
| unsaturated C═C double | DVB | — | 20 | — | — | — | — |
| bond-containing | BVPE | | | | | | |
| crosslinking agent | | — | — | 1 | — | — | — |
| curing accelerator | 25B | 1 | 0.1 | 3 | 1 | 0.1 | 3 |
| inorganic filler | SC2500- | 150 | 60 | 200 | 150 | 60 | 200 |
| | SVJ | | | | | | |
| solvent | toluene | PA | PA | PA | PA | PA | PA |
| property | unit | E8 | E9 | E10 | E11 | E12 | E13 |
| Tg | ° C. | 273 | 270 | 271 | 242 | 260 | 277 |
| Dk | / | 3.05 | 3.10 | 3.20 | 3.08 | 3.15 | 3.06 |
| Df | / | 0.0017 | 0.0017 | 0.0020 | 0.0019 | 0.0020 | 0.0019 |
| flame retardancy | / | V0 | V0 | V0 | V0 | V0 | V0 |
| Z-PTE | % | 0.8 | 0.6 | 0.7 | 1.4 | 1.2 | 0.7 |
| PCT | / | ◯◯◯ | ◯◯◯ | ◯◯◯ | ◯◯◯ | ◯◯◯ | ◯◯◯ |
| P/S | lb/in | 3.2 | 4.1 | 3.9 | 4.7 | 4.2 | 3.6 |

(PA represents proper amount.)

TABLE 3
The contents of the resin composition (in part by weight) of Comparative Examples
C1 to C7 and the testing results of the properties of articles made therefrom.

| component | | C1 | C2 | C3 | C4 | C5 | C6 | C7 |
|---|---|---|---|---|---|---|---|---|
| unsaturated C═C double | SA9000 | 100 | 100 | 100 | 100 | 100 | 100 | 100 |
| bond-containing | OPE-2st | — | — | — | — | — | — | — |
| polyphenylene ether | 1200 | | | | | | | |
| resin | OPE-2st | — | — | — | — | — | — | — |
| | 2200 | | | | | | | |
| phosphorus-containing | P1 | 0 | — | — | — | — | — | — |
| compound represented | P2 | — | — | — | — | — | — | — |
| by Formula (1) | P3 | — | — | — | — | — | — | — |
| | P4 | — | — | — | — | — | — | — |
| | P5 | — | — | — | — | — | — | — |
| prepolymer Y1 | | — | — | — | — | — | — | — |
| prepolymer Y2 | | — | — | — | — | — | — | — |
| prepolymer Y3 | | — | — | — | — | — | — | — |
| V1 | | — | 22.4 | — | — | — | — | — |
| DABPA | | — | — | 13.5 | — | — | — | — |
| 4-bromobenzocyclobutene | | — | — | 16.0 | — | — | — | — |
| DPO | | — | 17.6 | 17.6 | — | — | — | — |
| D1 | | — | — | — | 40 | — | — | — |
| D2 | | — | — | — | — | 40 | — | — |
| D3 | | — | — | — | — | — | 40 | — |
| D4 | | — | — | — | — | — | — | 40 |
| unsaturated C═C double | DVB | — | — | — | — | — | — | — |
| bond-containing | BVPE | — | — | — | — | — | — | — |
| crosslinking agent | | | | | | | | |
| curing accelerator | 25B | 1 | 1 | 1 | 1 | 1 | 1 | 1 |
| inorganic filler | SC2500- | 150 | 150 | 150 | 150 | 150 | 150 | 150 |
| | SVJ | | | | | | | |
| solvent | toluene | PA | PA | PA | PA | PA | PA | PA |
| property | unit | C1 | C2 | C3 | C4 | C5 | C6 | C7 |
| Tg | ° C. | 205 | 225 | 196 | 219 | 216 | 212 | 211 |
| Dk | / | 3.30 | 3.40 | 3.45 | 3.28 | 3.26 | 3.30 | 3.30 |
| Df | / | 0.0023 | 0.0045 | 0.0058 | 0.0031 | 0.0029 | 0.0032 | 0.0023 |
| flame retardancy | / | V2 | V1 | V0 | V0 | V0 | V0 | V0 |
| Z-PTE | % | 1.8 | 1.8 | 2.3 | 1.8 | 1.8 | 1.9 | 1.8 |
| PCT | / | XXX | XXX | XXX | ◯XX | ◯◯X | ◯XX | ◯XX |
| P/S | lb/in | 4.5 | 2.8 | 3.1 | 4.0 | 3.9 | 4.2 | 3.4 |

(PA represents proper amount.)

The following observations can be made from Table 1 to Table 3:
1. Examples E1 to E10 which use the phosphorus-containing compound represented by Formula (1) and Examples E11 to E13 which use the prepolymer of the present disclosure have a significant improvement in the following properties: Tg, Dk, Df, flame retardancy, Z-PTE and PCT, compared to Comparative Example C1 which does not comprise the phosphorus-containing compound represented by Formula (1) or the prepolymer of the present disclosure. Among them. Tg of Comparative Example C1 is 205° C., while Tg of Examples E1 to E13 are all greater than or equal to 240° C.; Dk of Comparative Example C1 is 3.30, while Dk of Examples E1 to E13 are all lower than or equal to 3.20; Df of Comparative Example C1 is 0.0023, while Df of Examples E1 to E13 are all lower than or equal to 0.0020; the flame retardancy of Comparative Example C1 is V2, while the flame retardancy of Examples E1 to E13 are all V0; Z-PTE of Comparative Example C1 is 1.8%, while Z-PTE of Examples E1 to E13 are all lower than or equal to 1.5%; Comparative Example C1 has delamination in the PCT, while Examples E1 to E13 all have no delamination in the PCT.
2. Examples E1 to E10 which use the phosphorus-containing compound represented by Formula (1) and Examples E11 to E13 which use the prepolymer of the present disclosure have a significant improvement in the following properties: Tg. Dk, Df, Z-PTE and PCT, compared to the mixture using V1 and DPO (Comparative Example C2) and the mixture using DABPA, 4-bromobenzocyclobutene and DPO (Comparative Example C3). Among them, Tg of Comparative Examples C2 and C3 are all lower than 240° C., while Tg of Examples E1 to E13 are all greater than or equal to 240° C.; Dk of Comparative Examples C2 and C3 are all greater than 3.20, while Dk of Examples E1 to E13 are all lower than or equal to 3.20; Df of Comparative Examples C2 and C3 are all great than 0.0020, while Df of Examples E1 to E13 are all lower than or equal to 0.0020; Z-PTE of Comparative Examples C2 and C3 are all greater than 1.5%, while Z-PTE of Examples E1 to E13 are all lower than or equal to 1.5%; Comparative Examples C2 and C3 all have delamination in the PCT, while Examples E1 to E13 all have no delamination in the PCT.
3. Examples E1 to E10 which use the phosphorus-containing compound represented by Formula (1) and Examples E11 to E13 which use the prepolymer of the present disclosure have a significant improvement in the following properties: Tg, Dk, Df, Z-PTE and PCT, compared to the phosphorus-containing compound using other structures (Comparative Example C4 to C7). Among them, Tg of Comparative Examples C4 to C7 are all lower than 240° C., while Tg of Examples E1 to E13 are all greater than or equal to 240° C.; Dk of Comparatives Example C4 to C7 are all greater than 3.20, while Dk of Examples E1 to E13 are all lower than or equal to 3.20; Df of Comparative Examples C4 to C7 are all greater than 0.0020, while Df of Examples E1 to E13 are all lower than or equal to 0.0020; Z-PTE of Comparative Examples C4 to C7 are all greater than 1.5%, while Z-PTE of Examples E1 to E13 are all lower than or equal to 1.5%; Comparative Examples C4 to C7 all have different degree of delamination in the PCT, while Examples E1 to E13 all have no delamination in the PCT.

The above detailed description is merely illustrative in nature and is not intended to limit the embodiments of the present disclosure or the application or uses of such embodiments. As used herein, the term “example” or similar expression means “serving as an example, instance, or illustration.” Any implementation described herein as exemplary is not necessary to be construed as preferred or advantageous over other implementations, unless otherwise specified.

Moreover, while at least one exemplary example or comparative example has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments and equivalents thereof. Also, the scope defined by the claims includes known equivalents and foreseeable equivalents at the time of filing this patent application.

What is claimed is:

1. A phosphorus-containing compound, represented by Formula (1): 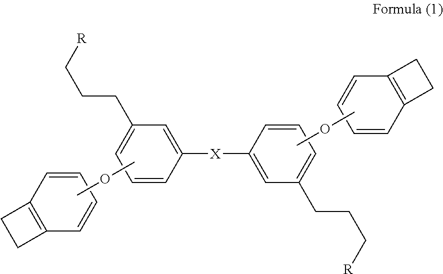
wherein in Formula (1), X is a covalent bond or a C1-C3 alkyl group,
each of R is independently a group represented by Formula (2), Formula (3) or Formula (4) 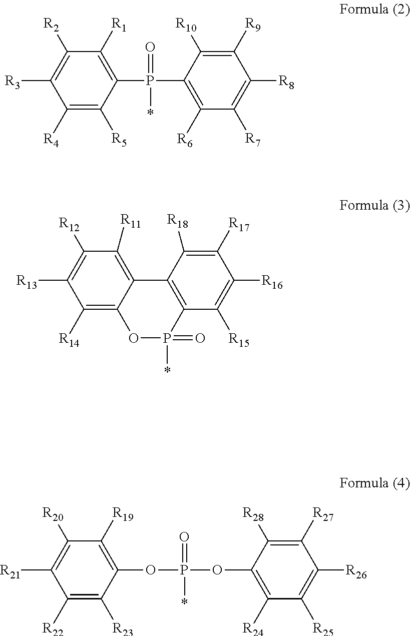
wherein each of R₁ to R₂₈ is independently a hydrogen atom or a C1-C3 alkyl group.

2. The phosphorus-containing compound according to claim 1, wherein the phosphorus-containing compound is any one of phosphorus-containing compounds represented by Formula (5) to Formula (9),

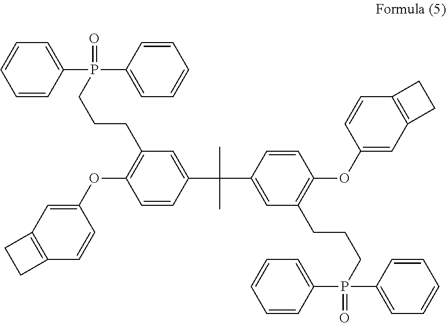 [SMILES: CC(C)(c1ccc(Oc2ccc3c(c2)CC3)c(CCCP(=O)(c2ccccc2)c2ccccc2)c1)c1ccc(Oc2ccc3c(c2)CC3)c(CCCP(=O)(c2ccccc2)c2ccccc2)c1]

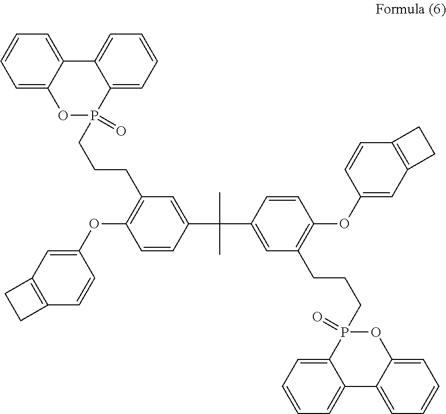 [SMILES: CC(C)(c1ccc(Oc2ccc3c(c2)CC3)c(CCCP2(=O)Oc3ccccc3-c3ccccc32)c1)c1ccc(Oc2ccc3c(c2)CC3)c(CCCP2(=O)Oc3ccccc3-c3ccccc32)c1]

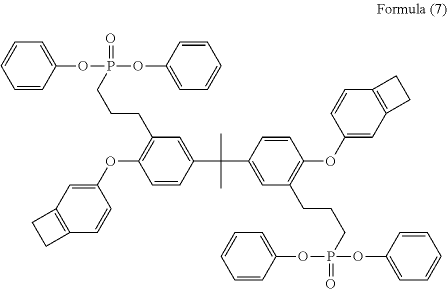 [SMILES: CC(C)(c1ccc(Oc2ccc3c(c2)CC3)c(CCCP(=O)(Oc2ccccc2)Oc2ccccc2)c1)c1ccc(Oc2ccc3c(c2)CC3)c(CCCP(=O)(Oc2ccccc2)Oc2ccccc2)c1]

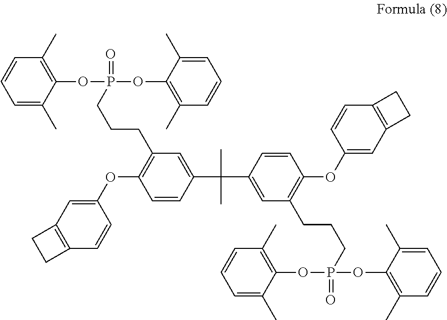 [SMILES: Cc1cccc(C)c1OP(=O)(CCCc1cc(C(C)(C)c2ccc(Oc3ccc4c(c3)CC4)c(CCCP(=O)(Oc3c(C)cccc3C)Oc3c(C)cccc3C)c2)ccc1Oc1ccc2c(c1)CC2)Oc1c(C)cccc1C]

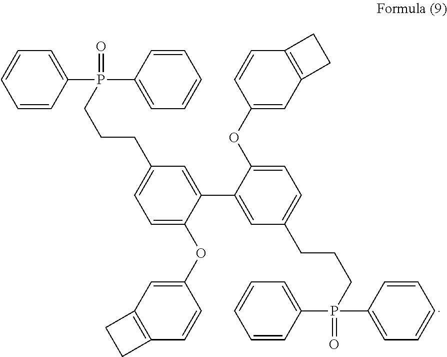 [SMILES: O=P(CCCc1ccc(Oc2ccc3c(c2)CC3)c(-c2cc(CCCP(=O)(c3ccccc3)c3ccccc3)ccc2Oc2ccc3c(c2)CC3)c1)(c1ccccc1)c1ccccc1]

3. A manufacturing method of the phosphorus-containing compound according to claim 1, comprising the following steps:
step (1): preparing a Grignard reagent of halobenzocyclobutene in a reaction vessel;
step (2): reacting diallylbisphenol with one or more of compound R—H in another reaction vessel to obtain an intermediate compound 1, wherein in the compound R—H, H represents a hydrogen atom, and R is a group represented by Formula (2), Formula (3) or Formula (4), 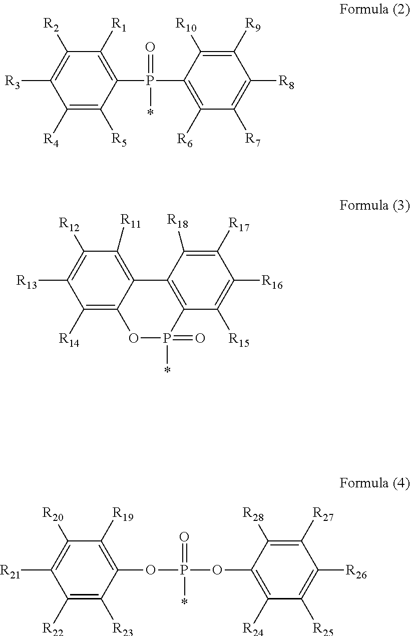
wherein each of R₁ to R₂₈ is independently a hydrogen atom or a C1-C3 alkyl group; and
step (3): reacting the Grignard reagent of halobenzocyclobutene prepared from the step (1) with the intermediate compound 1 to obtain the phosphorus-containing compound represented by Formula (1).

4. The manufacturing method of the phosphorus-containing compound according to claim 3, wherein
the reaction temperature for the step (1) is 0° C. to 100° C., and the reaction time for the step (1) is 1 to 10 hours,
in the step (2), the compound R—H is diphenylphosphine oxide, 9,10-dihydro-9-oxa-10-phosphaphenanthrene-10-oxide, diphenyl phosphate or bis(2,6-dimethylphenyl)phosphate, and the molar ratio of the compound R—H to the diallylbisphenol is 2:1 to 3:1,
the reaction temperature for the step (2) is 80° C. to 160° C., and the reaction time for the step (2) is 1 to 6 hours, and
the reaction temperature for the step (3) is-20° C. to 120° C., and the reaction time for the step (3) is 3 to 30 hours.

5. A resin composition, comprising the following components or a prepolymer thereof:
component (A): 100 parts by weight of an unsaturated C═C double bond-containing polyphenylene ether resin; and
component (B): 15 parts by weight to 90 parts by weight of the phosphorus-containing compound according to claim 1;
wherein the prepolymer is obtained from a mixture through prepolymerization, and the mixture comprises at least the component (A) and the component (B).

6. The resin composition according to claim 5, wherein the component (A) comprises any one of a (meth)acryloyl-containing polyphenylene ether resin, a vinylbenzyl-containing polyphenylene ether resin, and a vinyl-containing polyphenylene ether resin, or a combination thereof.

7. The resin composition according to claim 5, wherein the phosphorus-containing compound comprises any one of phosphorus-containing compounds represented by Formula (5) to Formula (9), or a combination thereof,

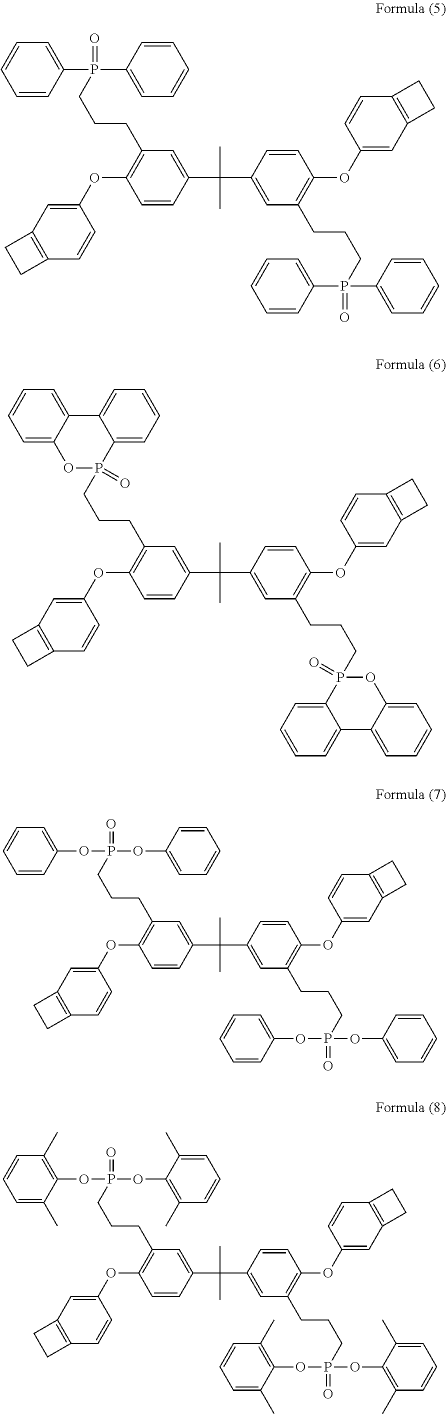 [SMILES: CC(C)(c1ccc(Oc2ccc3c(c2)CC3)c(CCCP(=O)(c2ccccc2)c2ccccc2)c1)c1ccc(Oc2ccc3c(c2)CC3)c(CCCP(=O)(c2ccccc2)c2ccccc2)c1 ; CC(C)(c1ccc(Oc2ccc3c(c2)CC3)c(CCCP2(=O)Oc3ccccc3-c3ccccc32)c1)c1ccc(Oc2ccc3c(c2)CC3)c(CCCP2(=O)Oc3ccccc3-c3ccccc32)c1 ; CC(C)(c1ccc(Oc2ccc3c(c2)CC3)c(CCCP(=O)(Oc2ccccc2)Oc2ccccc2)c1)c1ccc(Oc2ccc3c(c2)CC3)c(CCCP(=O)(Oc2ccccc2)Oc2ccccc2)c1 ; Cc1cccc(C)c1OP(=O)(CCCc1cc(C(C)(C)c2ccc(Oc3ccc4c(c3)CC4)c(CCCP(=O)(Oc3c(C)cccc3C)Oc3c(C)cccc3C)c2)ccc1Oc1ccc2c(c1)CC2)Oc1c(C)cccc1C]

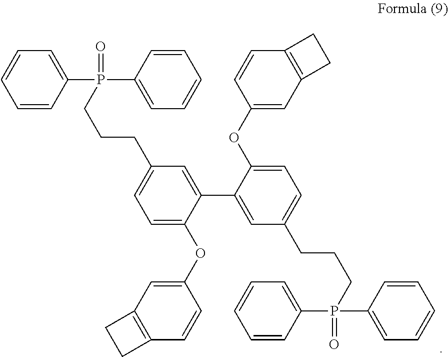 [SMILES: O=P(CCCc1ccc(Oc2ccc3c(c2)CC3)c(-c2cc(CCCP(=O)(c3ccccc3)c3ccccc3)ccc2Oc2ccc3c(c2)CC3)c1)(c1ccccc1)c1ccccc1]

8. The resin composition according to claim 5, wherein the prepolymer is formed from the component (A) and the component (B) through prepolymerization, and the conversion rate of the prepolymerization is 10% to 99%.

9. The resin composition according to claim 5, wherein the resin composition further comprises any one of an unsaturated C═C double bond-containing crosslinking agent, an organic silicone resin, a benzoxazine resin, an epoxy resin, a polyester resin, a phenol resin, an amine curing agent, a polyamide, a polyimide, a styrene maleic anhydride, a maleimide resin, a cyanate ester resin, and a maleimide triazine resin, or a combination thereof.

10. The resin composition according to claim 5, wherein the resin composition further comprises any one of a curing accelerator, a polymerization inhibitor, an inorganic filler, a surfactant, a coloring agent, and a solvent, or a combination thereof.

11. An article made from the resin composition according to claim 5, comprising a prepreg, a resin film, a laminate or a printed circuit board.

12. The article according to claim 11, wherein the article has at least one of the following properties:
a glass transition temperature as measured by reference to IPC-TM-650 2.4.24.4 of greater than or equal to 240° C.;
a dielectric constant at 10 GHz as measured by reference to JISC2565 of less than or equal to 3.20;
a dissipation factor at 10 GHz as measured by reference to JISC2565 of less than or equal to 0.0020;
a flame retardancy as measured by reference to UL94 rating of V0;
a percent thermal expansion at Z-axis as measured by reference to IPC-TM-650 2.4.24.5 of less than or equal to 1.5%;
no delamination occurs after subjecting the article to a heat resistance after moisture absorption test by reference to IPC-TM-650 2.6.16.1 and IPC-TM-650 2.4.23; and
a copper foil peeling strength as measured by reference to IPC-TM-650 2.4.8 of greater than or equal to 3.2 lb/in.
